(19) United States
(12) Patent Application Publication
(10) Pub. No.: US 2012/0097534 A1
(43) Pub. Date: Apr. 26, 2012

(54) MAGNETRON SPUTTERING CATHODE AND FILM FORMATION APPARATUS

(75) Inventors: Hirohisa Takahashi, Sammu-shi (JP); Shinya Yamada, Sammu-shi (JP); Satoru Ishibashi, Sammu-shi (JP); Kouhei Sakuma, Sammu-shi (JP)

(73) Assignee: ULVAC, INC., Chigasaki-shi (JP)

(21) Appl. No.: 13/060,623

(22) PCT Filed: Aug. 28, 2009
(86) PCT No.: PCT/JP2009/004240

§ 371 Date: May 11, 2011

(30) Foreign Application Priority Data
Aug. 29, 2008 (JP) 2008-222170

(51) Int. Cl. C23C 14/35

(52) U.S. Cl. 204/298.12; 204/298.19

(57) ABSTRACT

A magnetron sputtering cathode includes: a yoke; a magnetic circuit having a central magnet portion, a peripheral edge magnet portion, an auxiliary magnet portion, and a parallel area; and a backing plate. The central magnet portion, the peripheral edge magnet portion, and the auxiliary magnet portion are disposed so that polarities of tip portions of the central magnet portion, the peripheral edge magnet portion, and the auxiliary magnet portion are different from each other at portions between adjacent magnet portions. The magnetic field profile observed from above of the backing plate and the magnetic flux density in a horizontal direction are determined so that the magnetic flux density in a first area is a positive value and the magnetic flux density in a second area is a negative value with respect to a position corresponding to the central magnet portion as a boundary.

### BACKGROUND OF THE INVENTION

1. Field of the Invention

The present invention relates to a magnetron sputtering cathode, and more particularly, to a magnetron sputtering cathode capable of improving utilization efficiency of a target and a film formation apparatus having the same.

The present application claims a priority of Japanese Patent Application No. 2008-222170, filed Aug. 29, 2008, the contents of which are incorporated herein by reference.

2. Background Art

Conventionally, in order to successively form an oxide-based transparent conductor film such as an ITO (Indium Tin Oxide) film on a large-scaled glass substrate such as a liquid crystal display (LCD) or a plasma display panel (PDP) with a uniform thickness, a magnetron sputtering apparatus has been proposed.

In this sputtering apparatus, a plurality of magnetic circuits are arranged on a rear surface of the target, and a substrate is arranged on the surface of the target, plasma is generated in the vicinity of the surface of the target by the magnetic field generated from the magnetic circuit, and a film is thereby formed on the substrate.

If a conventional magnetic circuit for the magnetron sputter is used, the utilization efficiency of the target ranges from approximately 20 to 30%.

When the utilization efficiency of the target is low in this manner, the lifetime of the target is reduced; therefore, there is problems in that the material cost of the target, the labor cost for replacing the target, the cost for bonding the target, or the like increase, and productivity is thereby degraded.

Three examples of cathodes for addressing such problems have been proposed as follows.

In Japanese Unexamined Patent Application, First Publication No. H5-25625, a structure is disclosed in which an auxiliary magnet is arranged between the principal magnets.

However, in such a structure in which the auxiliary magnet is just simply arranged, it is difficult to increase the utilization efficiency of the target, and it is difficult to say that optimization is achieved.

In Japanese Patent No. 3473954, another structure is disclosed in which the utilization efficiency of the target is improved by setting up a complicated magnetic circuit.

However, since such a magnetic circuit is very complicated, and a number of magnets are used, the cost increases.

Furthermore, since a number of magnets are used, it is necessary to take the effect of the magnetic field generated in each magnet into account, a limitation occurs in a distance between the target surface and the magnetic circuit, and it is necessary to shorten the distance between the target surface and the magnetic circuit.

For this reason, since the magnetic field reaches just a short distance from the magnet surface, it is difficult to increase the thickness of the target.

For example, as apparent from FIG. 4 of Japanese Patent No. 3473954, the depth of the erosion is shallow in the center of the target.

It is envisaged that the erosion is generated because of the influence described above.

In Japanese Unexamined Patent Application, First Publication No. 2006-16634 or Japanese Unexamined Patent Application, First Publication No. H2-34780, a method is disclosed in which the magnetic field is optimized as well as the shape of the magnetic circuit.

In Japanese Unexamined Patent Application, First Publication No. 2006-16634 or Japanese Unexamined Patent Application, First Publication No. H2-34780, a plate-shaped magnetic body is arranged so as to provide an area where values of the vertical magnetic field components of the magnetic field in regard to the surface of the target are flatly distributed at zero or in the vicinity of zero or an area crossing the zero point three times.

However, in Japanese Unexamined Patent Application, First Publication No. 2006-16634, since a definition of the vertical magnetic field component of the magnetic field is insufficient, as in Japanese Patent No. 3473954, the center of the target disclosed in Japanese Unexamined Patent Application, First Publication No. 2006-16634 is not actively sputtered, and thus, erosion having a shape that is not sufficiently used is generated.

In addition, although Japanese Unexamined Patent Application, First Publication No. H2-34780 discloses a structure for changing the relative position of the magnet, it is difficult to generate a sufficient magnetic field using this structure, and erosion having a shape that is not sufficiently utilized is generated.

As described above, conventionally, while various ideas have been proposed to improve the utilization efficiency of the target, most of the studies in a conventional technique focus on a structure for enlarging the erosion area of the target by forming a magnetic circuit to increase the magnetic field parallel to the surface of the target and preventing concentration of plasma on the surface of the target.

Even when the cathode structure disclosed in Japanese Patent No. 3473954 and Japanese Unexamined Patent Application, First Publication No. 2006-16634 described above is employed, the utilization efficiency of the target is approximately 50%.

Therefore, it is desired to develop the magnetron sputtering cathode having the utilization efficiency of the target exceeding 50%.

In addition, in a conventional cathode, when the target has a thickness less than or equal to 10 mm, it is possible to obtain the utilization efficiency of the target described above.

However, if the target has a thickness of approximately 10 mm, lifetime thereof is reduced, and, as a result, this may increase the material cost of the target, the labor cost for replacing the target, the cost for bonding the target, or the like, thus degrading productivity.

For this reason, it is desired to develop a magnetron sputtering cathode having the utilization efficiency of the target exceeding 50% and capable of applying the target having a thickness greater than or equal to 10 mm.

### SUMMARY OF THE INVENTION

The present invention has been made to address the aforementioned problems, and provides a magnetron sputtering cathode capable of obtaining a utilization efficiency of the target exceeding 50%.

A magnetron sputtering cathode of a first aspect of the present invention includes: a yoke having a plate shape and having a surface and a central area; a magnetic circuit provided at the surface of the yoke, the magnetic circuit having a central magnet portion that is linearly disposed at the central area of the yoke, a peripheral edge magnet portion that is disposed in the periphery of the central magnet portion, an auxiliary magnet portion that is disposed between the central magnet portion and the peripheral edge magnet portion, and a parallel area where the central magnet portion, the peripheral edge magnet portion, and the auxiliary magnet portion are parallel to each other; and a backing plate disposed so as to be superimposed on the magnetic circuit.

In the magnetron sputtering cathode, the central magnet portion, the peripheral edge magnet portion, and the auxiliary magnet portion are disposed so that polarities of tip portions of the central magnet portion, the peripheral edge magnet portion, and the auxiliary magnet portion are different from each other at portions between adjacent magnet portions.

In the magnetron sputtering cathode, in a cross direction which crosses the central magnet portion, the peripheral edge magnet portion, and the auxiliary magnet portion in the parallel area, and in an axial direction orthogonal to a direction in which the central magnet portion is extended, a magnetic field profile is obtained by observing toward the peripheral edge magnet portion from the central magnet portion and by observing from above of the backing plate. The magnetic flux density in a horizontal direction in the magnetic field profile on a face parallel to the backing plate is determined so that the magnetic flux density in a first area is a positive value and the magnetic flux density in a second area is a negative value with respect to a position corresponding to the central magnet portion as a boundary.

In the magnetron sputtering cathode of the first aspect of the invention, it is preferable that the positive or negative sign of value of the magnetic flux density of the horizontal direction be reversed at the near peripheral edge magnet portion.

In the magnetron sputtering cathode of the first aspect of the invention, it is preferable that a magnetic flux density in a vertical direction on a surface parallel to the backing plate be symmetrical with respect to a position corresponding to the central magnet portion as a boundary, and each of the first area and the second area has three points where the magnetic flux density in the vertical direction be zero.

In the magnetron sputtering cathode of the first aspect of the invention, it is preferable that the maximum intensity of the magnetic flux density in the horizontal direction be 100 gauss to 600 gauss.

It is preferable that the magnetron sputtering cathode of the first aspect of the invention further include a control unit adjusting the distance between the backing plate and the magnetic circuit.

A film formation apparatus of a second aspect of the present invention includes the above-described the magnetron sputtering cathode.

### Advantageous Effects of Invention

In the magnetron sputtering cathode of the present invention, in the cross direction which crosses the central magnet portion, the peripheral edge magnet portion, and the auxiliary magnet portion in the parallel area, and in an axial direction orthogonal to the direction in which the central magnet portion is extended, the magnetic field profile is obtained by observing toward the peripheral edge magnet portion from the central magnet portion and by observing from above of the backing plate; and the magnetic flux density (B_{//}) in the horizontal direction in the magnetic field profile on the face parallel to the backing plate is determined so that the magnetic flux density in the first area is the positive value and the magnetic flux density in the second area is the negative value with respect to the position corresponding to the central magnet portion as a boundary.

Consequently, the local concentration of plasma is eased on the surface of the target, and plasma is generated so as to spread from the center of the target toward the peripheral edge of the first area and the second area.

For this reason, the target is sputtered across a wider area of the surface of the target. As a result, it is possible to widen the portion of the target at which erosion occurs in comparison with that of a conventional target. Therefore, it is possible to improve the utilization efficiency of the target.

### BRIEF DESCRIPTION OF THE DRAWINGS

FIG. 1A is a cross-sectional view schematically illustrating a magnetron sputtering cathode according to a first embodiment of the present invention.

FIG. 1B is a plan view schematically illustrating a magnetron sputtering cathode according to the first embodiment of the present invention.

FIG. 1C is a diagram illustrating a magnetic field profile observed in the magnetron sputtering cathode according to the first embodiment of the present invention, in which a parallel magnetic field component and a vertical magnetic field component on the surface of the target are shown.

FIG. 2 is a diagram schematically illustrating a magnetic field line and plasma obtained in the magnetron sputtering cathode of the present invention.

FIG. 3A is a diagram schematically illustrating plasma generated when the magnetic flux density in the horizontal direction of the magnetic field profile at the peripheral edge of the target is greater than zero, and illustrating a case where the magnetic flux density in the horizontal direction at the peripheral edge of the target is not reversed.

FIG. 3B is a diagram illustrating the depth of erosion of the target 40 and the magnetic field profile of FIG. 3A.

FIG. 4 is a diagram illustrating a magnetic field profile measured by changing the maximum intensity of the magnetic flux density in the horizontal direction within the magnetic field profile.

FIG. 5A is a diagram illustrating erosion of the target obtained in the case where the maximum intensity of the magnetic flux density in the horizontal direction is 1200 gauss.

FIG. 5B is a diagram illustrating erosion of the target obtained in the case where the maximum intensity of the magnetic flux density in the horizontal direction is 1200 gauss, in which a target where erosion is locally observed is illustrated.

FIG. 6A is a diagram illustrating a magnetic field profile observed in the magnetron sputtering cathode of the present invention.

FIG. 6B is a diagram schematically illustrating a magnetic field line obtained in the magnetron sputtering cathode of the present invention.

FIG. 7 is a diagram schematically illustrating erosion of the target obtained in the magnetron sputtering cathode of the present invention.

FIG. 8A is a diagram schematically illustrating a magnetron sputtering cathode according to a second embodiment of the present invention.

FIG. 8B is a diagram illustrating a magnetic field profile observed in the magnetron sputtering cathode according to the second embodiment of the present invention.

FIG. 9A is a diagram schematically illustrating a magnetron sputtering cathode according to a third embodiment of the present invention.

FIG. 9B is a diagram illustrating a magnetic field profile observed in the magnetron sputtering cathode according to the third embodiment of the present invention.

FIG. 10A is a diagram schematically illustrating a magnetron sputtering cathode according to a fourth embodiment of the present invention.

FIG. 10B is a diagram illustrating a magnetic field profile observed in the magnetron sputtering cathode according to the fourth embodiment of the present invention.

FIG. 11A is a diagram schematically illustrating a magnetron sputtering cathode according to a fifth embodiment of the present invention.

FIG. 11B is a diagram illustrating a magnetic field profile observed in the magnetron sputtering cathode according to the fifth embodiment of the present invention.

FIG. 12A is a diagram schematically illustrating a magnetron sputtering cathode according to a sixth embodiment of the present invention.

FIG. 12B is a diagram illustrating a magnetic field profile observed in the magnetron sputtering cathode according to the sixth embodiment of the present invention.

FIG. 13 is a diagram schematically illustrating an inline type film formation apparatus to which the magnetron sputtering cathode of the present invention is applied.

FIG. 14A is a top view schematically illustrating a single-wafer type film formation apparatus to which the magnetron sputtering cathode of the present invention is applied.

FIG. 14B is a cross-sectional view schematically illustrating a construction of the magnetron sputtering cathode when a DC power supply is used as a power supply in the single-wafer type film formation apparatus to which the magnetron sputtering cathode of the present invention is applied.

FIG. 14C is a cross-sectional view schematically illustrating a construction of the magnetron sputtering cathode when an AC power supply is used as a power supply in the single-wafer type film formation apparatus to which the magnetron sputtering cathode of the present invention is applied.

FIG. 15 is a cross-sectional view schematically illustrating a roll-to-roll type film formation apparatus to which the magnetron sputtering cathode of the present invention is applied.

FIG. 16 is a cross-sectional view schematically illustrating a carousel type film formation apparatus to which the magnetron sputtering cathode of the present invention is applied.

FIG. 17 is a diagram illustrating an erosion depth and a magnetic field profile of the magnetron sputtering cathode in Example 1.

FIG. 18 is a diagram illustrating an erosion depth and a magnetic field profile of the magnetron sputtering cathode in Example 2.

FIG. 19 is a diagram illustrating an erosion depth and a magnetic field profile of the magnetron sputtering cathode in Example 3.

### DESCRIPTION OF THE PREFERRED EMBODIMENTS

Hereinafter, embodiments of the present invention will be described in detail with reference to the accompanying drawings.

The technical scope of the invention is not limited to embodiments which will be described below, but various modifications may be made without departing from the scope of the invention.

### First Embodiment

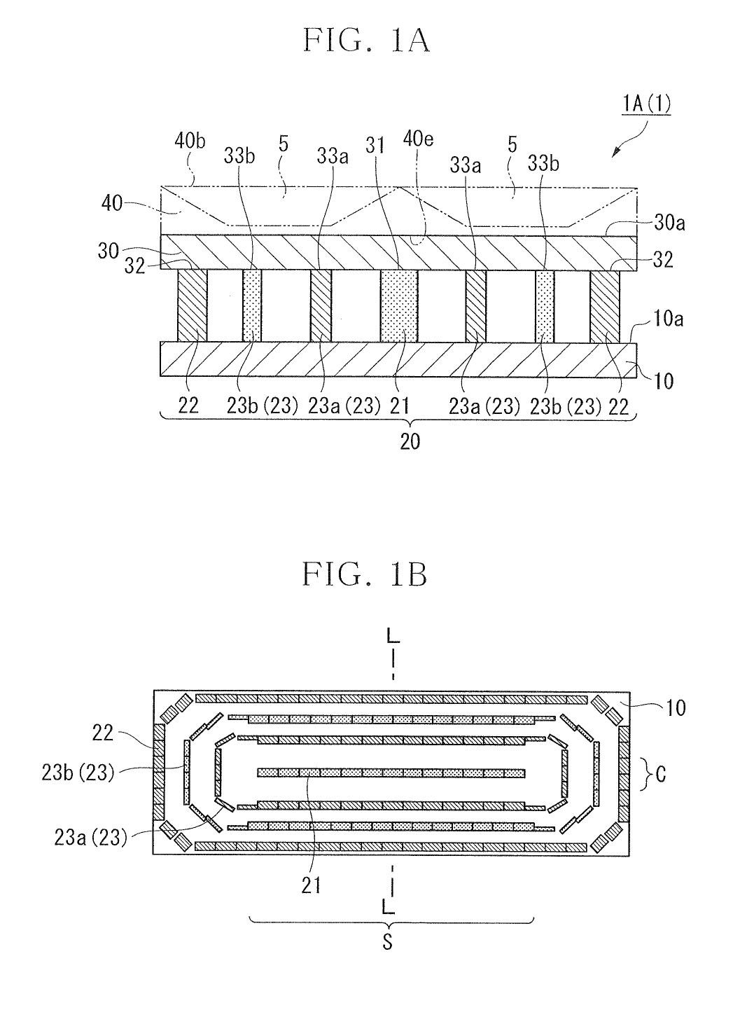

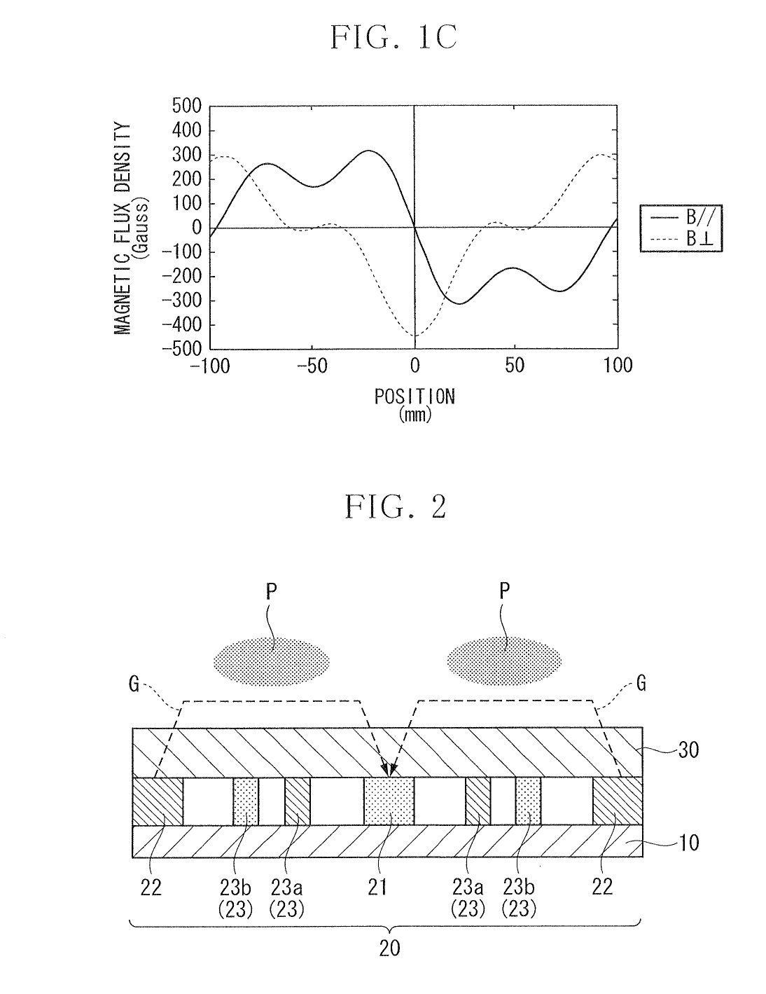

FIGS. 1A to 1C are diagrams schematically illustrating a magnetron sputtering cathode according to the first embodiment of the present invention and a magnetic field profile observed in the magnetron sputtering cathode.

FIG. 1A is a cross-sectional view schematically illustrating the magnetron sputtering cathode 1A, taken along the line L-L′ of FIG. 1B.

FIG. 1B is a plan view schematically illustrating the magnetic circuit arranged on the surface of the yoke.

FIG. 1C illustrates a magnetic field profile observed in the magnetron sputtering cathode of the present invention, in which a parallel magnetic field component and a vertical magnetic field component on the surface of the target are illustrated.

In FIG. 1C, the axis of abscissas corresponds to the position along the line L-L′ of FIG. 1B, i.e., the position of the widthwise direction of the magnetron sputtering cathode 1A.

On the axis of abscissas in FIG. 1C, the position of 0 mm corresponds to the position of the central magnet portion 21 described below. In other words, the axis of abscissas in FIG. 1C denotes a distance from the central magnet portion 21.

In addition, the axis of ordinate denotes the magnetic flux density.

The magnetron sputtering cathode 1 (1A) of the first embodiment includes a yoke 10 having a plate shape, a magnetic circuit 20 provided on the surface of the yoke 10, and a backing plate 30 arranged to overlap with the magnetic circuit 20.

In addition, the magnetic circuit 20 includes a central magnet portion 21 arranged in a straight line shape in the central area C of the yoke 10, a peripheral edge magnet portion 22 arranged in the periphery of the central magnet portion 21, and an auxiliary magnet portion 23 arranged between the central magnet portion 21 and the peripheral edge magnet portion 22.

In addition, the magnetic circuit 20 has a parallel area S where the central magnet portion 21, part of the peripheral edge magnet portion 22, and part of the auxiliary magnet portion 23 are parallel to each other.

In addition, the central magnet portion 21, the peripheral edge magnet portion 22, and the auxiliary magnet portion 23 are arranged such that polarities of the tip portions (31, 32, 33a, and 33b) of the central magnet portion 21, the peripheral edge magnet portion 22, and the auxiliary magnet portion 23 are different from each other at portions between adjacent magnet portions.

In an axial direction perpendicular to the direction in which the central magnet portion 21 extends (the straight line portion of the central magnet portion 21) as a direction crossing the central magnet portion 21, the peripheral edge magnet portion 22, and the auxiliary magnet portion 23 in the parallel area S, the magnetic field profile observed from the central magnet portion 21 to the peripheral edge magnet portion 22 above the backing plate 33 is determined such that the magnetic flux density (B_{//}) of the horizontal direction on the surface parallel to the backing plate 33 has a positive value in the first area (one area) or a negative value in the second area (the other area) with respect to the position corresponding to the central magnet portion 21 as a boundary.

In addition, the magnetic field profile observed above the backing plate 33 refers to the magnetic field profile observed in the position where the target is arranged.

Hereinafter, the magnetron sputtering cathode 1A (1) will be described in detail.

FIGS. 1A to 1C illustrate an example in which the auxiliary magnet portion 23 is constituted of a first auxiliary magnet portion 23a and a second auxiliary magnet portion 23b, and the central magnet portion 21 is surrounded by the first auxiliary magnet portion 23a and the second auxiliary magnet portion 23b.

Here, when the tip portion 31 of the central magnet portion 21 and the tip portion 33b of the second auxiliary magnet portion 23b have a North polarity N, the tip portion 33a of the first auxiliary magnet portion 23a and the tip portion 32 of the peripheral edge magnet portion 22 have a South polarity S.

In addition, when the tip portion 31 of the central magnet portion 21 and the tip portion 33b of the second auxiliary magnet portion 23b have a South polarity S, the tip portion 33a of the first auxiliary magnet portion 23a and the tip portion 32 of the peripheral edge magnet portion 22 have a North polarity N.

In addition, the tip portions 31, 32, 33a, and 33b are the portions making contact with or facing the rear surface of the backing plate 30.

In addition, FIGS. 1A to 1C illustrate an example in which the target 40 is arranged on the backing plate 30.

The magnetic field profile is measured using a gauss meter within the range of 15 mm to 35 mm over the surface of the magnetic circuit 20.

For example, when the backing plate has a thickness of 15 mm, the magnetic field profile is measured within the range of 0 mm to 20 mm over the surface 30a of the backing plate 30.

In addition, the magnetron sputtering cathode 1A of the present invention may include any one of a DC power supply, an AC power supply, and an RF power supply.

The yoke 10 has a planar shape, and the surface 10a of the yoke 10 is provided with the magnetic circuit 20 (including a central magnet portion 21, a peripheral edge magnet portion 22, and an auxiliary magnet portion 23).

The yoke 10 is the type generally used in magnetron sputtering cathodes, but the type of the yoke is not particularly limited.

The yoke 10 may include, for example, ferrite-based stainless steel or the like.

In addition, the yoke 10 may have, for example, a width of approximately 200 mm.

The target 40 is placed on the surface 30a of the backing plate 30.

The backing plate 30 is a backing plate generally used in the magnetron sputtering cathode, and the type of the backing plate is not particularly limited.

In addition, although the first embodiment is an example of a case where the backing plate 30 is used, the present invention is not limited thereto, and the backing plate 30 may be omitted, or the target 40 may be arranged over the magnetic circuit 20.

In this case, it is possible to obtain the same effect as that of the case where the backing plate 30 is used.

For example, the magnetic permeability of the target 40 is preferably less than or equal to 3 H/m.

The target 40 includes, for example, a material containing an element selected from the group consisting of Mg, Ti, Zr, V, Nb, Ta, Cr, Mo, W, Pd, Pt, Cu, Ag, Au, Zn, Al, In, C, Si, and Sn as a main composition.

Preferably, a total thickness of the backing plate 30 and the target 40 is 15 to 35 mm.

For example, when the backing plate 30 having a thickness of 15 mm is used, the thickness of the target 40 is less than or equal to 20 mm.

In addition, when the backing plate is not used, the target 40 having a thickness less than or equal to 35 mm may be used.

The target 40 has, for example, a width of approximately 200 mm.

The magnetic circuit 20 is arranged on the surface 10a of the yoke 10 to generate a parallel magnetic field on the surface 40b of the target 40 and includes a central magnet portion 21, a peripheral edge magnet portion 22, and an auxiliary magnet portion 23.

In the first embodiment, the auxiliary magnet portion 23 includes a first auxiliary magnet portion 23a and a second auxiliary magnet portion 23b.

The central magnet portion 21 is arranged in a straight line shape in the center of the target 40 along the longitudinal direction of target 40.

The peripheral edge magnet portion 22 is arranged in the peripheral edge of the surface 10a of the yoke 10 to surround the central magnet portion 21 and has a portion parallel to the central magnet portion 21.

The first auxiliary magnet portion 23a and the second auxiliary magnet portion 23b are arranged on the surface 10a of the yoke 10 to surround the central magnet portion 21 and has a portion parallel to the central magnet portion 21.

The central magnet portion 21, the peripheral edge magnet portion 22, and the auxiliary magnet portion 23 may be formed of an anisotropically sintered magnet, a samarium-cobalt magnet, a ferrite magnet, or the like containing, for example, neodymium, iron, and boron as a main composition.

The heights and widths of the central magnet portion 21, the peripheral edge magnet portion 22, and the auxiliary magnet portion 23, and the distance between each magnet portions may be appropriately adjusted to satisfy the magnetic field profile shown in FIG. 1C.

For example, in the case where the central magnet portion 21, the peripheral edge magnet portion 22, and the auxiliary magnet portion 23 are formed of an anisotropically sintered magnet containing neodymium, iron, and boron as a main composition, the height of each magnet portion is 30 mm, the width of the central magnet portion 21 is 15 mm, the width of the first auxiliary magnet portion 23a is 12.5 mm, the width of the second auxiliary magnet portion 23b is 7.5 mm, and the width of the peripheral edge magnet portion 22 is 12.5 mm.

In addition, as the distance between each magnet portion, the distance between the central magnet portion 21 and the first auxiliary magnet portion 23a is 21 mm, the distance between the first auxiliary magnet portion 23a and the second auxiliary magnet portion 23b is 20 mm, and the distance between the second auxiliary magnet portion 23b and the peripheral edge magnet portion 22 is 15 mm.

The magnetic flux density (B_{//}) in the horizontal direction generated from the surface 40b of the target 40 (over the backing plate 30) by the magnetic circuit 20 is a positive value in the first area and a negative value in the second area from the central magnet portion 21 to the peripheral edge magnet portion 22 as shown in FIG. 1C.

In addition, the magnetic flux density (B_{//}) in the horizontal direction is distributed so as to have point symmetry with respect to the original point of the FIG. 1C.

For this reason, the magnetic field line G and distribution of plasma P are generated as shown in FIG. 2, and it is possible to enlarge the area where the erosion of the target 40 is generated.

In addition, in FIG. 1C, the first area includes the second and third quadrants, and the second area includes the first and fourth quadrants.

In addition, the magnetic flux density (B_{//}) in the horizontal direction is preferably such that the positive or negative sign is reversed (opposite signs) at the near peripheral edge magnet portion 22.

In other words, the magnetic flux density (B_{//}) in the horizontal direction is preferably negative in the first area and positive in the second area at the near peripheral edge magnet portion.

Next, a case where the magnetic flux density (B_{//}) in the horizontal direction is not reversed in the circumference of the peripheral edge magnet portion 22 (the peripheral edge of the target 40) will be described.

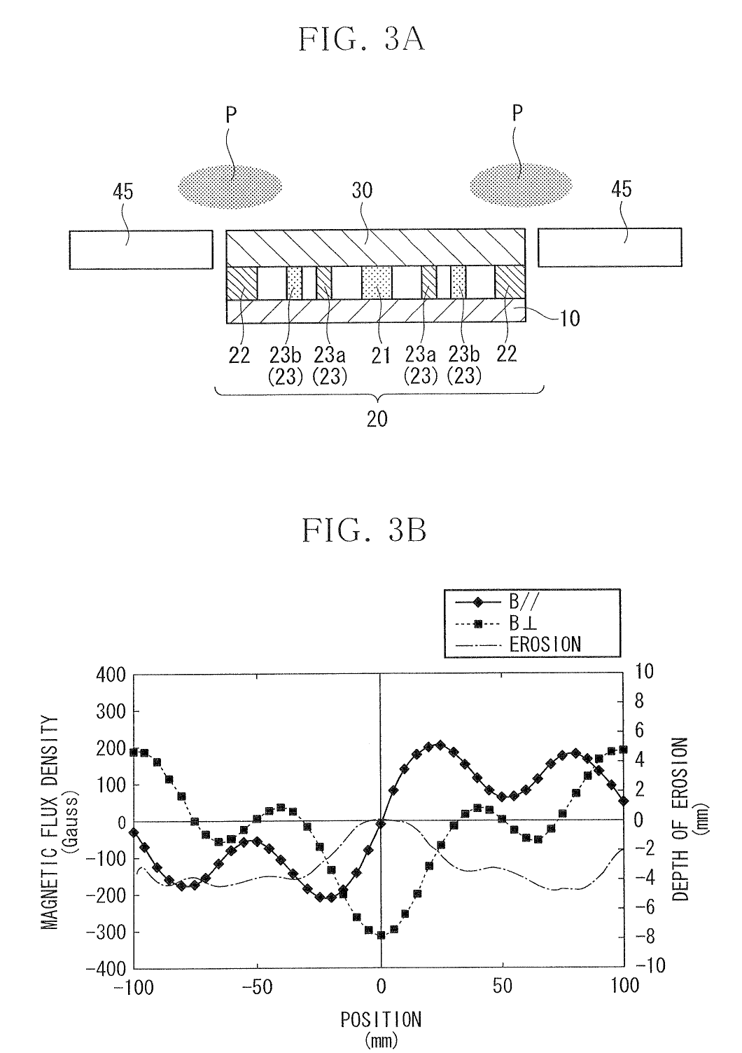

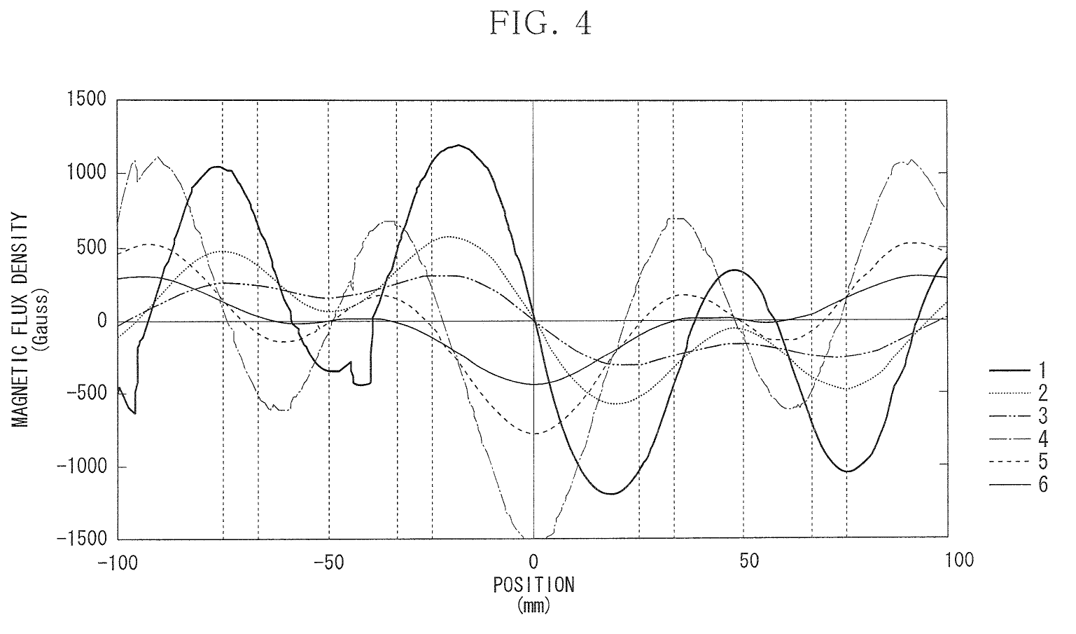

FIG. 3A is a diagram schematically illustrating plasma when the magnetic flux density in the horizontal direction is not reversed at the peripheral edge of the target.

FIG. 3B is a diagram illustrating the depth of erosion in the target 40 and the magnetic field profile of FIG. 3A.

In FIG. 3B, the axis of abscissas denotes the position of the widthwise direction of the magnetron sputtering cathode, and the axis of ordinate denotes the depth of erosion and the magnetic flux density.

In addition, in FIG. 3B, the position of 0 mm on the axis of abscissas corresponds to the position of the central magnet portion. In other words, the axis of abscissas in FIG. 3B denotes the distance from the central magnet portion.

As shown in FIGS. 3A and 3B, in the circumference of the peripheral edge magnet portion 22 (the peripheral edge of the target 40), if the magnetic flux density (B_{//}) in the horizontal direction is not reversed, the Lorentz force is applied to electrons at the outer side of the target 40.

For this reason, plasma P spreads toward the earth shield, and plasma P generated as shown in FIG. 3A is shifted to the peripheral edge of the target 40.

For this reason, as shown in FIG. 3B, the sputtering is made up to the peripheral edge of the target 40.

In addition, a non-erosion portion where erosion is not generated is formed in the center of the target 40.

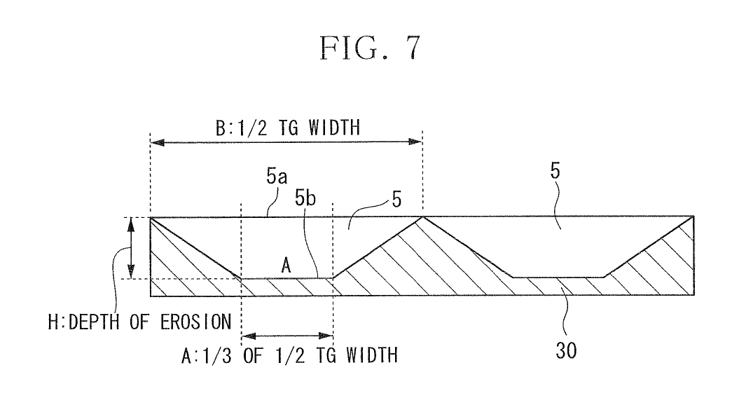

In addition, the cross-sectional shape of the portion where the erosion is generated is not trapezoidal as shown in FIG. 1A or 7.

Therefore, the utilization efficiency of the target 40 is degraded.

In contrast, as shown in the magnetic field profile of FIG. 1C according to the first embodiment of the present invention, in the magnetic field profile of the peripheral edge of the target 40, the Lorentz force applied to electrons is generated in the opposite direction to the progressing direction by reversing the magnetic flux density (B_{//}) in the horizontal direction. Therefore, it is difficult to generate electric discharge in the peripheral edge of the target 40.

As a result, plasma P is not shifted to the earth shield 45 but is formed to spread from the center of the target 40 (the area where the central magnet portion 21 is arranged) toward the peripheral edge (the area where the peripheral edge magnet portion 22 is arranged).

For this reason, the target 40 is sputtered across a wider area than that of the surface 40b.

Thus, the cross-sectional shape of the erosion 5 of the target 40 becomes trapezoidal, and it is possible to widen the shape of the erosion 5 in comparison with the erosion formed in a conventional target. Therefore, it is possible to improve the utilization efficiency of the target 40.

In this case, it is preferable that the maximum intensity of the magnetic flux density (B_{//}) in the horizontal direction on the surface 40b of the target 40 is 100 gauss to 600 gauss.

FIG. 4 illustrates a magnetic field profile when the maximum intensity of the magnetic flux density (B_{//}) in the horizontal direction is changed to 300 gauss, 600 gauss, and 1200 gauss.

In FIG. 4, the axis of abscissas denotes a distance from the central magnet portion 21.

The axis of ordinate denotes the magnetic flux density.

In addition, on the axis of abscissas in FIG. 4, the position of 0 mm corresponds to the position of the central magnet portion 21.

In FIG. 4, the reference numerals 1, 2, and 3 denote the magnetic field profiles when the maximum intensity of the magnetic flux density (B_{//}) in the horizontal direction is 1200, 600, and 300 gauss, respectively.

In addition, the reference numerals 4, 5, and 6 denote the magnetic field profiles of the magnetic flux density (B_{⊥}) in the vertical direction corresponding to the reference numerals 1, 2, and 3, respectively.

The maximum intensity of the magnetic flux density (B_{//}) in the horizontal direction becomes 300 gauss by setting the distance (T/M) between the surface 40b of the target 40 and the magnetic circuit 20 to 35 mm. The maximum intensity of the magnetic flux density (B_{//}) in the horizontal direction becomes 600 gauss by setting the distance (T/M) to 25 mm. The maximum intensity of the magnetic flux density (B_{//}) in the horizontal direction becomes 1200 gauss by setting the distance (T/M) to 15 mm.

From FIG. 4, it was observed that the polarity of the magnetic flux density (B_{//}) in the horizontal direction is reversed when the maximum intensity of the magnetic flux density (B_{//}) in the horizontal direction is 1200 gauss.

In this manner, in the magnetron sputtering cathode having the magnetic field profile where the polarity is reversed, the plasma is concentrated near the area where the intensity of the magnetic flux density (B_{⊥}) in the vertical direction on the surface parallel to the backing plate becomes zero on the surface of the target.

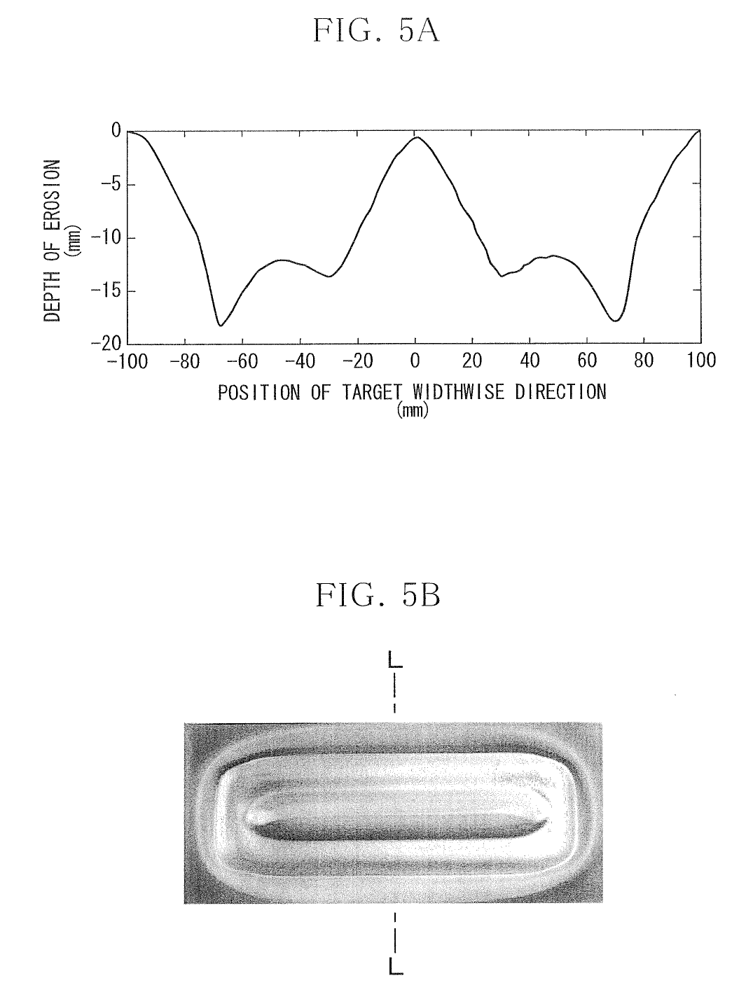

Therefore, as shown in FIGS. 5A and 5B, local erosion is observed in the area where the plasma is concentrated.

FIG. 5A is a diagram illustrating a relationship between the position of the widthwise direction of the target and the depth of erosion. FIG. 5B is a diagram illustrating the target 40 where the locally generated erosion is observed.

In this phenomenon, it is recognized that the maximum intensity of the magnetic flux density (B_{//}) in the horizontal direction exceeds 600 gauss.

In other words, in the case where the backing plate having, for example, a thickness of 15 mm and the target having a thickness of 20 mm are used, the initial T/M value before the sputtering is initiated is 35 mm, and the maximum intensity of the magnetic flux density (B_{//}) in the horizontal direction is 300 gauss. However, in the case where the erosion progresses, and erosion, for example, having a thickness exceeding 10 mm is generated, the T/M value becomes lower than 25 mm, and the maximum intensity of the magnetic flux density (B_{//}) in the horizontal direction has a value exceeding 600 gauss.

In this case, since the local erosion is generated as described above, as the erosion progresses, it is necessary to adjust the distance between the target 40 and the magnetic circuit 20 (necessary to separate the magnetic circuit 20 from the target 40) such that the maximum intensity of the magnetic flux density (B_{//}) in the horizontal direction becomes 100 gauss to 600 gauss.

In order to adjust the distance between the target 40 and the magnetic circuit 20, a control unit is used for moving the magnetic circuit 20 in the Z-axis direction as described below.

In contrast, as the maximum intensity of the magnetic flux density (B_{//}) in the horizontal direction is reduced under 100 gauss, electric discharge does not occur, and it is not possible to carry out sputtering.

In the magnetron sputtering cathode 1A according to the first embodiment, it is possible to obtain the magnetic field profile as shown in FIG. 1C.

In addition, it is preferable that the magnetic field profile of the magnetic flux density of the vertical direction have three points where the magnetic flux density of the vertical direction becomes zero in each of the first and second areas.

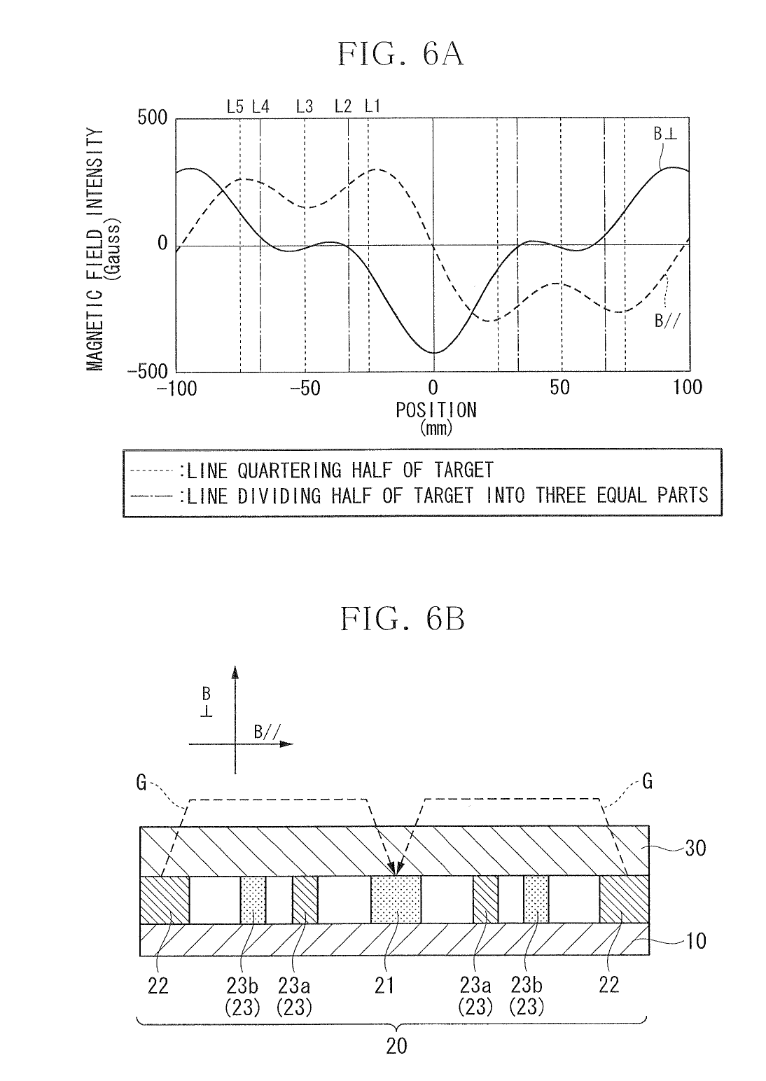

Specifically, as shown in FIGS. 6A and 6B, in the axial direction perpendicular to the straight line portion of the central magnet portion 21 of the target 40 in the first area, portions at which the half of the target 40 is further quartered are L1, L3, and L5. In the axial direction perpendicular to the straight line portion of the central magnet portion 21 of the target 40, portions at which the half of the target 40 is further divided into three equal parts are L2 and L4.

It is preferable that the magnetic field profile of magnetic flux density (B_{⊥}) of the vertical direction on the surface parallel to the target 40 have three crossings in the areas L2 to L4.

In addition, it is preferable that a position where the value becomes zero at the center of the magnetic field profile of the magnetic flux density (B_{⊥}) of the vertical direction is located at near L3.

In addition, it is preferable that the magnitudes of two peaks of the magnetic flux density (B_{//}) of the horizontal direction be equal to each other, each peak be located at near L1 and L5, and the bottom of the distribution of the magnetic flux density (B_{//}) of the horizontal direction be located at near L3.

If the magnetron sputtering cathode according to the present embodiment has the magnetic field profile described above, the plasma P spreads around L3, and the cross-sectional shape of the erosion 5 becomes a perfect trapezoid as shown in FIG. 7, so that it is possible to further improve the utilization efficiency of the target 40.

In this case, in the cross-sectional shape of the erosion 5, the upper base 5a (the surface 40b side of the target 40) of the trapezoid becomes half of the width of the target 40, and the lower base 5b (the back surface 40e of the target 40) of the trapezoid 5 becomes approximately ⅙ of the width of the target 40 (refer to FIG. 7).

In addition, in FIG. 7, “½ TG width” denotes “half of the width of the target”.

If the aforementioned conditions are satisfied, it is possible to use a target 40 having a thickness of approximately 20 mm, and it is possible to obtain the utilization efficiency of approximately 60%.

In addition, the utilization efficiency of the target 40 can be calculated based on the change of the weight of the target 40 before and after use (the weight of the target 40 after use/the weight of the target 40 before use).

In addition, while the magnetic field profile in the first area has been described in the first embodiment, the magnetic field profile of the second area is similar to that of the first area.

However, the sign of the value of the magnetic flux density (B_{//}) of the horizontal direction in the second area is opposite to the sign of the value of the magnetic flux density (B_{//}) of the horizontal direction in the first area.

### Second Embodiment

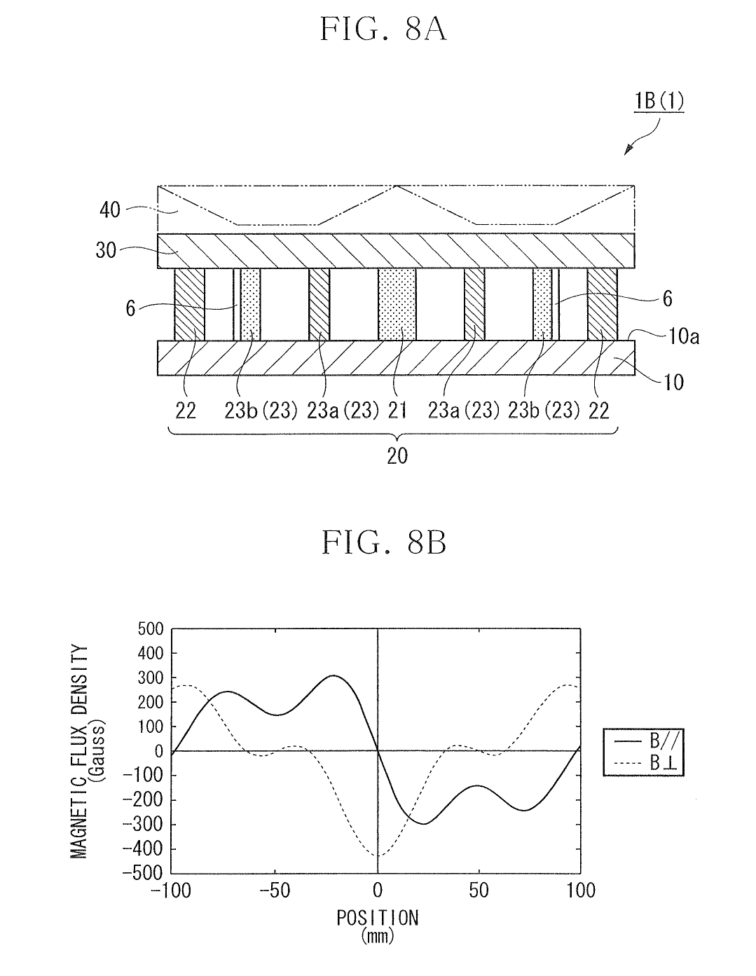

FIGS. 8A and 8B are diagrams schematically illustrating the magnetron sputtering cathode 1B (1) according to the second embodiment of the present invention.

FIG. 8A is a cross-sectional view schematically illustrating the magnetron sputtering cathode 1B. FIG. 8B is a diagram illustrating the magnetic field profile observed in the magnetron sputtering cathode 1B according to the second embodiment.

In FIG. 8B, the axis of abscissas corresponds to the position of the widthwise direction of the magnetron sputtering cathode 1B.

In the axis of abscissas in FIG. 8B, the position of 0 mm corresponds to the position of the central magnet portion 21 described below. In other words, the axis of abscissas in FIG. 8B denotes the distance from the central magnet portion 21.

In addition, the axis of ordinate denotes the magnetic flux density.

The magnetron sputtering cathode 1B according to the second embodiment is different from the magnetron sputtering cathode 1A according to the first embodiment in that the shunt 6 is arranged in the side surface of the second auxiliary magnet portion 23b.

The shunt 6 is provided to adjust the magnetic field of each magnet portion, and any shunt known in the art may be used depending on the magnetic forces of the central magnet portion 21, the peripheral edge magnet portion 22, the first auxiliary magnet portion 23a, and the second auxiliary magnet portion 23b, or the like.

While the shunt 6 arranged at the outer side surface of the second auxiliary magnet portion 23b is shown as an example in the second embodiment, the shape of the shunt 6 is not limited thereto.

For example, the shunt 6 may be provided in the central magnet portion 21, the first auxiliary magnet portion 23a, or the side surface of the peripheral edge magnet portion 22.

In addition, the shunt 6 may be provided in the inner side surface of the magnet portion instead of the outer side surface of the magnet portion.

The size of the shunt 6 is appropriately adjusted to obtain the magnetic field profile shown in FIG. 8B depending to the magnetic force of each used magnet portion, the distance from the magnet portion to the surface 40b of the target 40, or the like.

Even when the shunt 6 is provided at the side surface of the magnet as in the second embodiment, the heights and the widths of each magnet portion, and the distance between each magnet portion may be appropriately adjusted to satisfy the magnet field profile as described in the first embodiment in conjunction with FIG. 8B.

For example, in the case where the central magnet portion 21, the peripheral edge magnet portion 22, and the auxiliary magnet portion 23 are made of an anisotropically sintered magnet containing neodymium, iron, and boron as a main composition, the height of each magnet portion is 30 mm, the width of the central magnet portion 21 is 15 mm, the width of the first auxiliary magnet portion 23a is 12.5 mm, the width of the second auxiliary magnet portion 23b is 7.5 mm, and the width of the peripheral edge magnet portion 22 is 12.5 mm.

In addition, as distances between each magnet portion, the distance between the central magnet portion 21 and the first auxiliary magnet portion 23a is 21 mm, the distance between the first auxiliary magnet portion 23a and the second auxiliary magnet portion 23b is 20 mm, and the distance between the second auxiliary magnet portion 23b and the peripheral edge magnet portion 22 is 15 mm.

In this case, when the shunt 6 is made of, for example, SUS430, a member having a width of 5 mm and a height of 30 mm (the same height as that of the magnet) may be used.

Even when the shunt 6 is arranged in the side surface of the magnet, and the magnet field is adjusted as described in the second embodiment, the magnetron sputtering cathode 1B has the same magnet field profile as that of the first embodiment as shown in FIG. 8B. Therefore, it is possible to obtain the same effect as that of the first embodiment described above.

### Third Embodiment

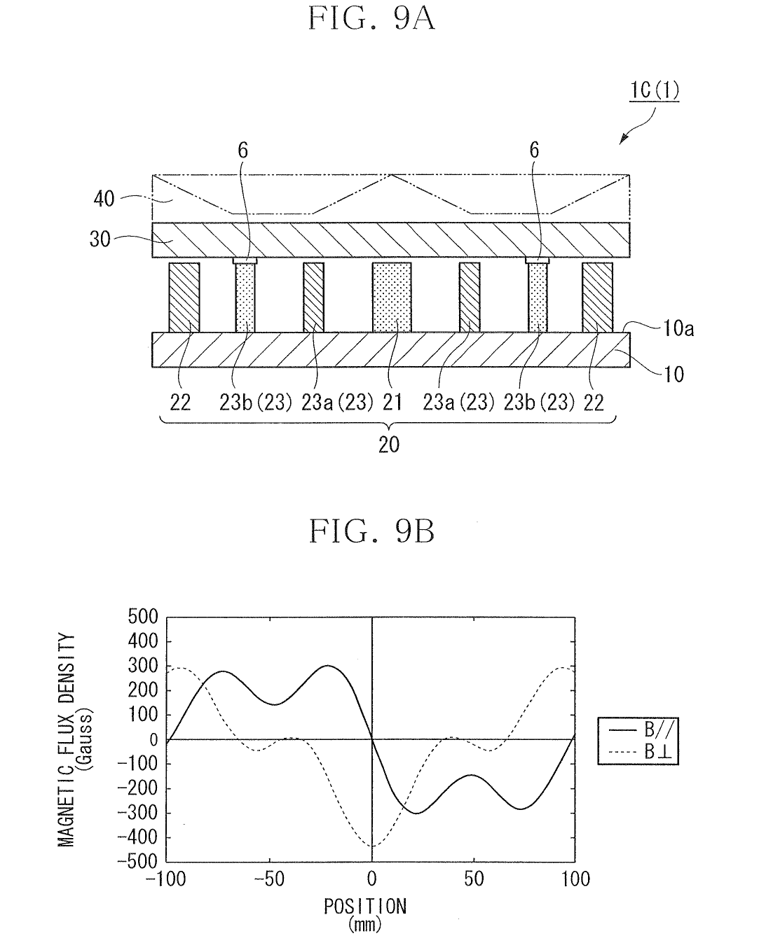

FIGS. 9A and 9B are diagrams schematically illustrating the magnetron sputtering cathode 1C (1) according to the third embodiment of the present invention.

FIG. 9A is a cross-sectional view schematically illustrating the magnetron sputtering cathode 1C, and FIG. 9B is a diagram illustrating the magnetic field profile observed in the magnetron sputtering cathode 1C of the third embodiment.

In FIG. 9B, the axis of abscissas corresponds to the position of the widthwise direction of the magnetron sputtering cathode 1C.

On the axis of abscissas in FIG. 9B, the position of 0 mm corresponds to the position of the central magnet portion 21 described below. In other words, the axis of abscissas in FIG. 9B denotes a distance from the central magnet portion 21.

In addition, the axis of ordinate denotes the magnetic flux density.

The magnetron sputtering cathode 1C of the third embodiment is different from the magnetron sputtering cathode 1A of the first embodiment in that the shunt 6 is arranged between the magnet portion and the target 40 (the backing plate 30 in the example of FIG. 9A).

The shunt 6 is provided to adjust the magnetic field of each magnet portion, and the same shunt as that of the second embodiment is used.

In the third embodiment, an example is illustrated in which the shunt 6 is arranged between the second auxiliary magnet portion 23b and the backing plate 30.

In the third embodiment, such a construction is not limited. For example, the shunt 6 may be provided between the central magnet portion 21, the first auxiliary magnet portion 23a, or the peripheral edge magnet portion 22 and the backing plate 30.

In addition, when the backing plate 30 is not used, the shunt 6 may be provided between each magnet portion and the target 40.

Even when the shunt 6 is provided between the magnetic circuit 20 and the target 40 (the backing plate 30 in the example of FIG. 9A) as in the third embodiment, the height and the widths of the magnet portions 21, 22, 23a, and 23b, and the distance between each magnet portion are appropriately adjusted to satisfy the magnetic field profile of the first embodiment as shown in FIG. 9B.

For example, in the case where the magnet portions 21, 22, 23a, and 23b are made of an anisotropically sintered magnet containing neodymium, iron, and boron as a main composition, the height of each magnet portion is 30 mm, and the width of the central magnet portion 21 is 15 mm, the width of the first auxiliary magnet portion 23a is 12.5 mm, the width of the second auxiliary magnet portion 23b is 7.5 mm, and the width of the peripheral edge magnet portion 22 is 12.5 mm.

In addition, the distance between the central magnet portion 21 and the first auxiliary magnet portion 23a is 21 mm, the distance between the first auxiliary magnet portion 23a and the second auxiliary magnet portion 23b is 20 mm, and the distance between the second auxiliary magnet portion 23b and the peripheral edge magnet portion 22 is 15 mm.

In this case, for example, when SUS430 is used as shunt 6, a member having a thickness of 2 mm may be used.

If the shunt 6 is arranged between the magnetic circuit 20 and the backing plate 30, and the magnetic field is adjusted as in the third embodiment, the magnetron sputtering cathode 1C has the magnetic field profile as described in the first embodiment in conjunction with FIG. 9B. Therefore, it is possible to obtain the same effect as that of the first embodiment described above.

### Fourth Embodiment

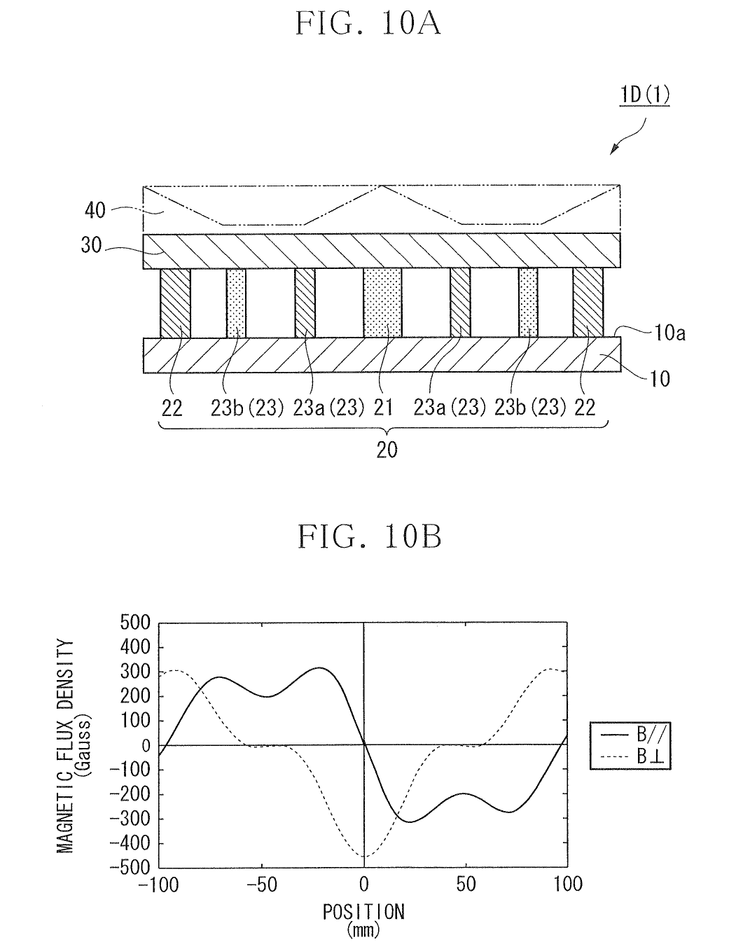

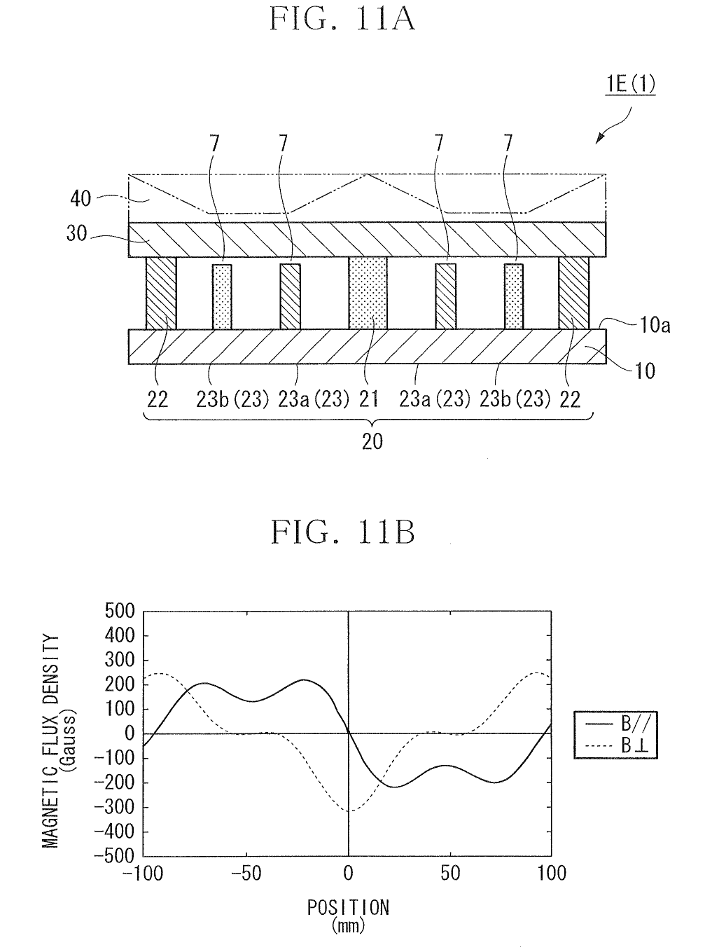

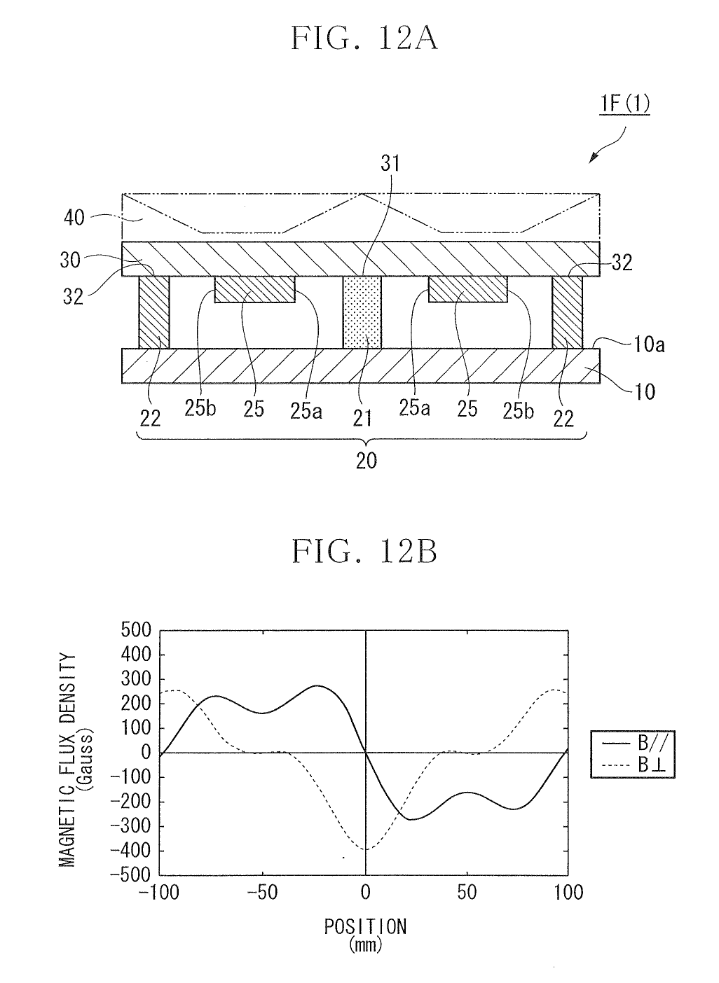

FIGS. 10A and 10B are diagrams schematically illustrating the magnetron sputtering cathode 1D (1) according to the fourth embodiment of the present invention.

FIG. 10A is a cross-sectional view schematically illustrating the magnetron sputtering cathode 1D, and FIG. 10B is a diagram illustrating the magnetic field profile observed in the magnetron sputtering cathode 1D of the fourth embodiment.

In FIG. 10B, the axis of abscissas corresponds to the position of the widthwise direction of the magnetron sputtering cathode 1D.

On the axis of abscissas in FIG. 10B, the position of 0 mm corresponds to the position of the central magnet portion 21 described below. In other words, the axis of abscissas in FIG. 10B denotes the distance from the central magnet portion 21.

In addition, the axis of ordinate denotes the magnetic flux density.

The magnetron sputtering cathode 1D of the fourth embodiment is different from the magnetron sputtering cathode 1A of the first embodiment in that materials of the first auxiliary magnet portion 23a and the second auxiliary magnet portion 23b are different from materials of the central magnet portion 21 and the peripheral edge magnet portion 22.

Specifically, for example, when the central magnet portion 21 and the peripheral edge magnet portion 24 are made of an anisotropically sintered magnet containing neodymium, iron, and boron as a main composition, the first auxiliary magnet portion 23a and the second auxiliary magnet portion 23b may be made of samarium-cobalt magnet, a ferrite magnet, or the like.

In addition, it is not necessary to change materials of the first auxiliary magnet portion 23a and the second auxiliary magnet portion 23b, but any one of materials of the magnet portions may be changed. In addition, the material of the central magnet portion 21 or the peripheral edge magnet portion 22 may be changed.

Even when the materials of each magnet portion are changed as in the fourth embodiment, the heights and the widths of the magnet portions 21, 22, 23a, and 23b, and the distance between each magnet portions are appropriately adjusted to satisfy the magnetic field profile similar to that of the first embodiment as shown in FIG. 10B.

For example, even when the central magnet portion 21 and the peripheral edge magnet portion 22 are made of an anisotropically sintered magnet containing neodymium, iron, and boron as a main composition, and the first auxiliary magnet portion 23a and the second auxiliary magnet portion 23b are made of a samarium-cobalt magnet or a ferrite magnet as described above, the height of each magnet portion is 30 mm, the width of the central magnet portion 21 is 15 mm, the width of the first auxiliary magnet portion 23a is 12.5 mm, the width of the second auxiliary magnet portion 23b is 9 mm, and the width of the peripheral edge magnet portion 22 is 12.5 mm.

In addition, the distance between the central magnet portion 21 and the first auxiliary magnet portion 23a is 18.5 mm, the distance between the first auxiliary magnet portion 23a and the second auxiliary magnet portion 23b is 19.5 mm, and the distance between the second auxiliary magnet portion 23b and the peripheral edge magnet portion 22 is 14 mm.

If the magnetic field is adjusted by changing the material of the magnet as in the fourth embodiment, the magnetron sputtering cathode 1D has the same magnetic field profile as that of the first embodiment shown in FIG. 10B. Therefore, it is possible to obtain the same effect as that of the first embodiment described above.

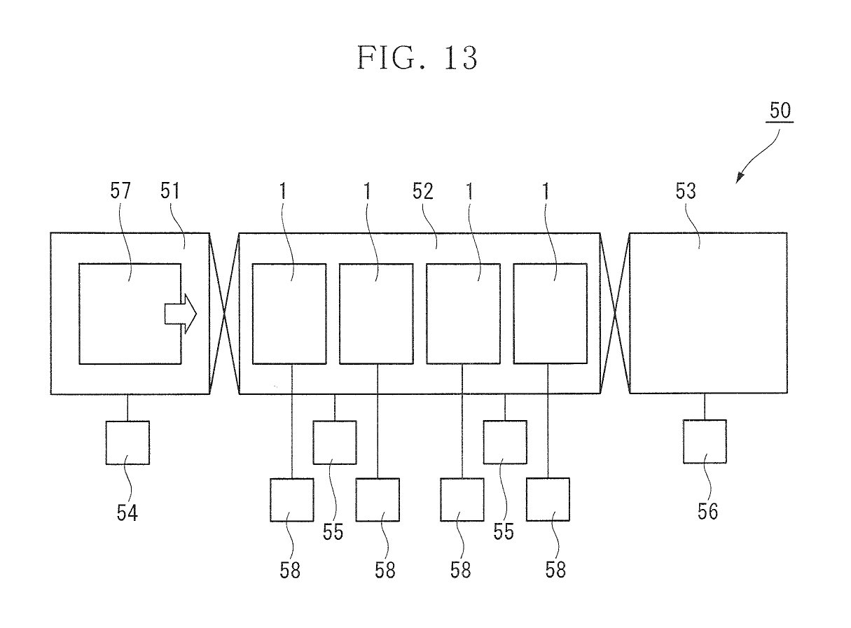

### Fifth Embodiment FIGS. 11A and 11B are diagrams schematically illustrating the magnetron sputtering cathode 1E (1) according to the fifth embodiment of the present invention.

FIG. 11A is a cross-sectional view schematically illustrating the magnetron sputtering cathode 1E, and FIG. 11B is a diagram illustrating the magnetic field profile obtained by the magnetron sputtering cathode 1E of the fifth embodiment.

In FIG. 11B, the axis of abscissas corresponds to the position of the widthwise direction of the magnetron sputtering cathode 1E.

On the axis of abscissas in FIG. 11B, the position of 0 mm corresponds to the position of the central magnet portion 21 described below. In other words, the axis of abscissas in FIG. 11B denotes the distance from the central magnet portion 21.

In addition, the axis of ordinate denotes the magnetic flux density.

The magnetron sputtering cathode 1E of the fifth embodiment is different from the magnetron sputtering cathode 1A of the first embodiment in the size of the magnet portion.

In the example of FIG. 11A, the heights of the first auxiliary magnet portion 23a and the second auxiliary magnet portion 23b are less than those of the magnet portions 21 and 22 so as to form gaps 7 between them and the backing plate 30.

In addition, it is not necessary to change the sizes of the first auxiliary magnet portion 23a and the second auxiliary magnet portion 23b, but any one of the magnet portions may be changed. Otherwise, the size of the central magnet portion 21 or the peripheral edge magnet portion 22 may be changed.

Any size of the magnet portion may be employed if it satisfies the magnetic field profile similar to that of the first embodiment shown in FIG. 11B. In addition, the size of the magnet portion is not particularly limited.

In addition, the magnet portion may be provided by appropriately adjusting the size thereof depending on the magnetic force of the magnet used in the magnetron sputtering cathode 1E.

For example, in the case where the magnet portions 21, 22, 23a, and 23b are made of an anisotropically sintered magnet containing neodymium, iron, and boron as a main composition, the width of the central magnet portion 21 is 15 mm, the width of the first auxiliary magnet portion 23a is 17 mm, the width of the second auxiliary magnet portion 23b is 13 mm, and the width of the peripheral edge magnet portion 22 is 12.5 mm.

In addition, the distance between the central magnet portion 21 and the first auxiliary magnet portion 23a is 12.5 mm, the distance between the first auxiliary magnet portion 23a and the second auxiliary magnet portion 23b is 23 mm, and the distance between the second auxiliary magnet portion 23b and the peripheral edge magnet portion 22 is 8 mm.

In this case, the height of the central magnet portion 21 is 30 mm, the height of the first auxiliary magnet portion 23a is 20 mm, the height of the second auxiliary magnet portion 23b is 20 mm, and the height of the peripheral edge magnet portion 22 is 30 mm.

If the magnetic field is adjusted by changing the size of the magnet as in the fifth embodiment, the magnetron sputtering cathode 1E has the same magnetic field profile as that of the first embodiment as shown in FIG. 11B. Therefore, it is possible to obtain the same effect as that of the first embodiment described above.

### Sixth Embodiment

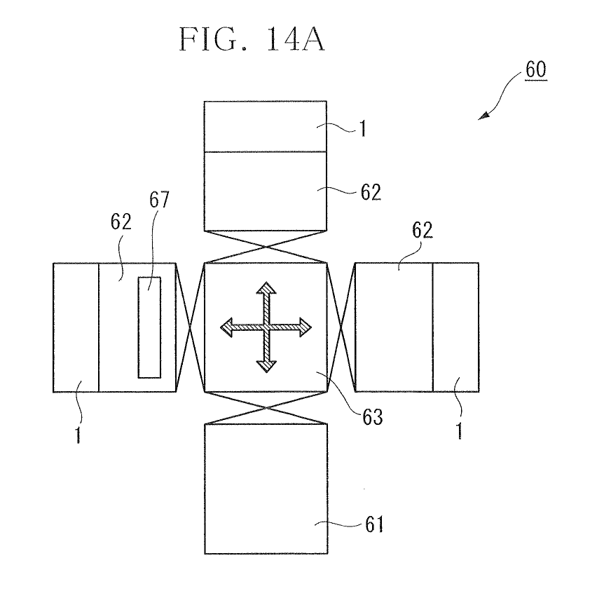

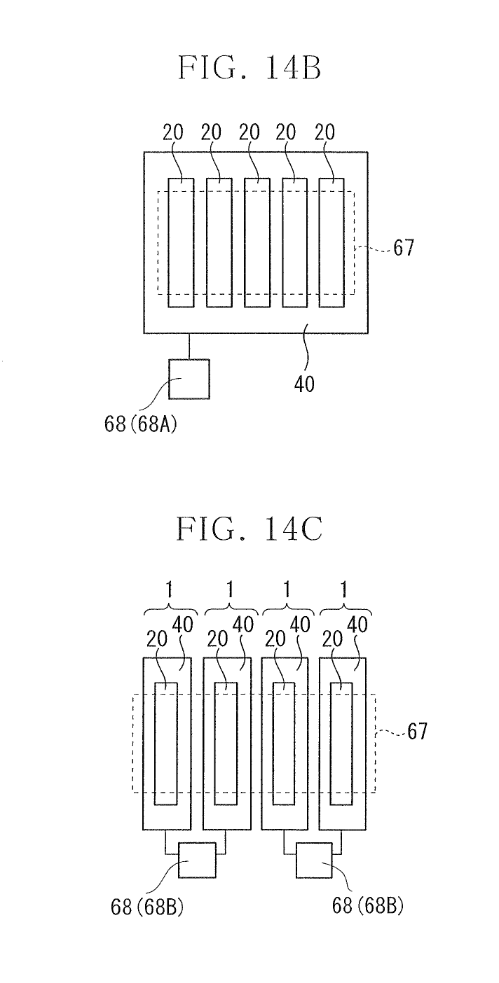

FIGS. 12A and 12B are diagrams schematically illustrating the magnetron sputtering cathode 1F (1) according to the sixth embodiment of the present invention.

FIG. 12A is a cross-sectional view schematically illustrating the magnetron sputtering cathode 1F, and FIG. 12B is a diagram illustrating the magnetic field profile observed in the magnetron sputtering cathode 1F of the sixth embodiment.

In FIG. 12B, the axis of abscissas corresponds to the widthwise direction of the magnetron sputtering cathode 1F.

On the axis of abscissas in FIG. 12B, the position of 0 mm corresponds to the position of the central magnet portion 21 described below. In other words, the axis of abscissas in FIG. 12B denotes the distance from the central magnet portion 21.

In addition, the axis of ordinate denotes the magnetic flux density.

The magnetron sputtering cathode 1F of the sixth embodiment is different from the magnetron sputtering cathode 1A of the first embodiment in that the first auxiliary magnet portion 23a and the second auxiliary magnet portion 23b are changed into a single auxiliary magnet portion 23 and laterally arranged on the rear surface 30b of the backing plate 30.

The auxiliary magnet portion 25 may be made of the same materials as those of the first auxiliary magnet portion 23a or the second auxiliary magnet portion 23b described above.

In addition, the first end 25a (one end, the end close to the central magnet portion 21) of the auxiliary magnet portion 25 has different polarity to that of the central magnet portion 21 (the tip portion 31), and the second end 25b (the other end, the end close to the peripheral edge magnet portion 22) of the auxiliary magnet portion 25 has the opposite polarity to that of the peripheral edge magnet portion 22 (the tip portion 32).

The size of the auxiliary magnet portion 25 is employed to satisfy the magnetic field profile similar to that the first embodiment as shown in FIG. 12B, and is not particularly limited.

In addition, the size of the auxiliary magnet portion 25 may be appropriately adjusted depending on the magnetic force or the like of the magnet used in the magnetron sputtering cathode 1F.

For example, in the case where the central magnet portion 21, the peripheral edge magnet portion 22, and the auxiliary magnet portion 25 are made of an anisotropically sintered magnet containing neodymium, iron, and boron as a main composition, the width of the central magnet portion 21 is 13 mm, the width of the auxiliary magnet portion 25 is 40.5 mm, and the width of the peripheral edge magnet portion 22 is 12.5 mm.

In addition, the distance between the central magnet portion 21 and the auxiliary magnet portion 25 is 27.5 mm, the distance between the auxiliary magnet portion 25 and the peripheral edge magnet portion 22 is 13 mm.

In addition, the heights of the central magnet portion 21 and the peripheral edge magnet portion 22 are 30 mm, and the height of the auxiliary magnet portion 25 is 13 mm.

If the first auxiliary magnet portion 23a and the second auxiliary magnet portion 23b are changed, and the auxiliary magnet portion 25 laterally arranged is arranged on the rear surface 30b of the baking plate 30 to adjust the magnetic field as in the sixth embodiment, the magnetron sputtering cathode 1F has the same magnetic field profile as that of the first embodiment as shown in FIG. 12B. Therefore, it is possible to obtain the same effect as that of the first embodiment described above.

In addition, it is preferable that the aforementioned magnetron sputtering cathode 1 (1A to 1E) according to the first to fifth embodiments has a control unit capable of moving the magnetic circuit 20 in the thickness direction (Z-axis direction) of the target 40, i.e., a control unit capable of moving the yoke 10 having the magnetic circuit 20 in the thickness direction of the target 40.

Even in the target 40 where erosion 5 progresses, it is possible to adjust the distance between the surface 40b of the target 40 and the magnetic circuit 20 by arranging the control unit and constantly maintain the magnetic field profile (the magnetic flux density (B_{//} and B_{⊥}) in the horizontal and vertical directions) on the surface 40b of the target 40.

In other words, even on the surface 40b of the target 40 where erosion 5 progresses, as described in conjunction with FIGS. 6A and 6B, the magnetic field profile is formed such that the magnetic flux density (B_{⊥}) of the vertical direction crosses the zero line three times in the areas L2 to L4, the position where a value becomes zero in the center of the magnetic flux density (B_{⊥}) of the vertical direction is located at near L3, the magnitudes of both peaks of the magnetic flux density (B_{//}) of the horizontal direction are equal, each of the peaks are located at near L1 and L5, respectively, and the bottom of the magnetic flux density (B_{//}) of the horizontal direction is located at near L3. Therefore, plasma spreads around L3.

For this reason, it is possible to prevent the one-sided hollow of the target that is generated by changing the progress rate of erosion between the inner and outer sides of the target as a conventional manner.

Therefore, even when the thickness of the target 40 is greater than or equal to 20 mm, the cross-sectional shape of the erosion 5 becomes a perfect trapezoid as shown in FIG. 7, and it is possible to further improve the utilization efficiency of the target 40.

As the control unit, a device capable of moving the magnetic circuit 20 in the Z-axis direction together with the yoke 10 is employed.

The type of the control unit is not particularly limited.

In addition, if the erosion 5 of the target 40 progresses so that the intensity of the magnetic field becomes strong, the voltage of the sputter decreases. Therefore, in the case where the power of the sputter is fixed, it is observed that the voltage drops, or the electric current increases.

Therefore, by monitoring the watt-hour or the voltage, it is possible to temporally adjust the distance between the magnetic circuit 20 and the surface 40b of the target 40.

Film formation apparatus

Next, the film formation apparatus to which the magnetron sputtering cathode 1 is applied according to the present invention will be described.

The magnetron sputtering cathode 1 of the present invention may be applied to, for example, an inline type film formation apparatus, a single-wafer type film formation apparatus, a roll-to-roll type film formation apparatus, a carousel type film formation apparatus, or the like.

Hereinafter, a film formation apparatus will be described.

Inline Type Film formation apparatus

FIG. 13 is a cross-sectional view schematically illustrating the inline type film formation apparatus 50 having the magnetron sputtering cathode 1 according to the present invention.

The inline type film formation apparatus 50 sequentially includes a preparation chamber 51, a film-formation chamber 52, and an ejection chamber 53.

In the film formation apparatus 50, the substrate 57 is supported in the vertical direction (the direction corresponding with the gravity direction) and introduced into the preparation chamber 51, and the preparation chamber is depressurized by the roughing-vacuum evacuation unit 54.

Next, the substrate 57 is delivered to the film-formation chamber 52 depressurized in a high vacuum by the high-vacuum evacuation unit 55, and film-formation process is carried out.

The substrate 51 that was subjected to the film-formation process is discharged from the ejection chamber 53 depressurized by the roughing-vacuum evacuation unit 56 to the external side of the film formation apparatus 50.

In the film-formation chamber 52, a plurality of magnetron sputtering cathodes 1 electrically connected to the power supply 58 are arranged side-by-side in the delivery direction of the substrate 57.

The power supply may include a DC power supply, an AC power supply, or an RF power supply.

While the substrate 57 passes in front of a plurality of magnetron sputtering cathodes 1, a thin film is formed on the surface of substrate 57 using each of the magnetron sputtering cathodes 1.

As a result, it is possible to form a homogeneous film on the substrate 57 and improve the throughput of the film-formation process.

By applying the magnetron sputtering cathode 1 according to the present invention to the inline type film formation apparatus 50, it is possible to improve the utilization efficiency of the target 40, extend the lifetime of the target 40, reduce the labor cost for replacing the target 40, the material cost of the target 40, the bonding cost of the target 40 decrease, and a down-time of the target 40, and improve productivity.

In addition, in comparison with the film formation apparatus having the vibrating cathode, the film formation apparatus of the present invention is compact.

In addition, since the vibration mechanism or the like is not necessary, it is possible to reduce the cost of the film formation apparatus.

Furthermore, in the case where the input power is fixed, the power is applied in a wide range, the power density per unit area decreases, and it is advantageous in the arcing.

Single-wafer Type Film formation apparatus

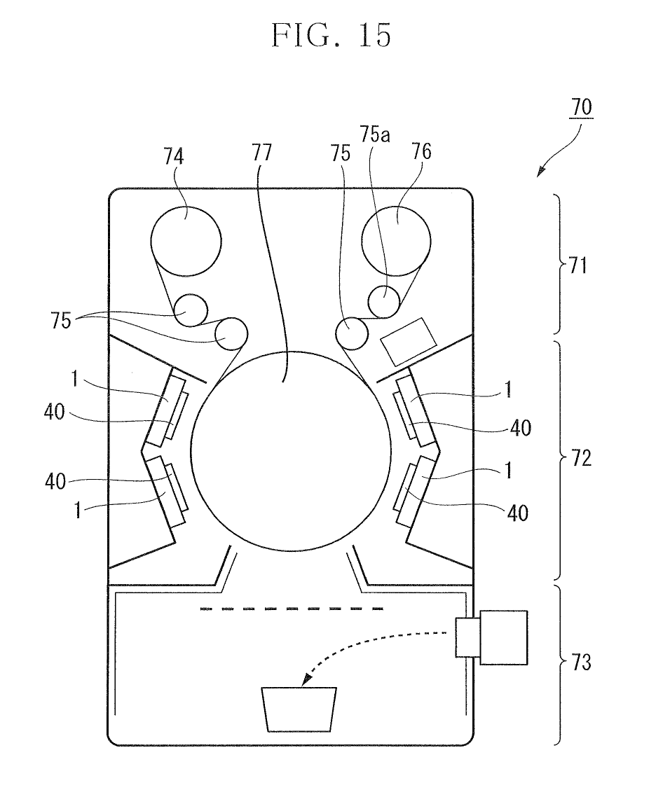

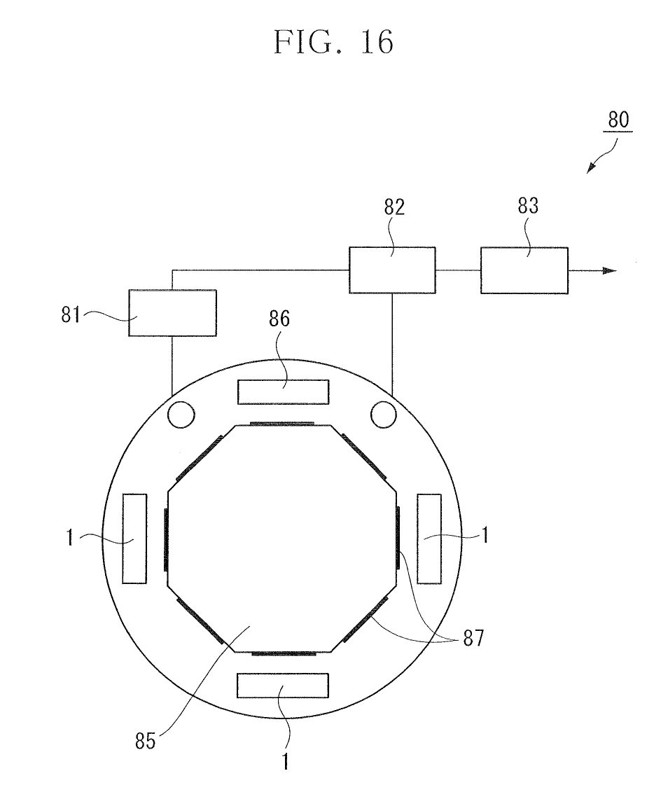

FIGS. 14A to 14C are diagrams schematically illustrating the single-wafer type film formation apparatus 60 having the magnetron sputtering cathode 1 of the present invention.

FIG. 14A is a top view illustrating the single-wafer type film formation apparatus 60.

FIG. 14B is a cross-sectional view schematically illustrating a construction of the magnetron sputtering cathode 1 when the DC power supply 68A is used as the power supply 68.

FIG. 14C is a cross-sectional view schematically illustrating a construction of magnetron sputtering cathode 1 when the AC power supply 68B is used as the power supply 68.

The single-wafer type film formation apparatus 60 includes a load lock chamber 61, a plurality of film-formation chambers 62, and a substrate delivery chamber 63.

The load lock chamber 61 temporarily stores the substrate 67 delivered from an apparatus different from the single-wafer type film formation apparatus 60 to the single-wafer type film formation apparatus 60 and the substrate on which a film is formed in the single-wafer type film formation apparatus 60.

The substrate temporarily stored in the load lock chamber 61, and the substrate on which a film was formed is transmitted to and received from an apparatus different from the single-wafer type film formation apparatus 60.

In a plurality of film-formation chambers 62 (three chambers in FIG. 14A), a thin film is formed on the substrate 67.

The substrate delivery chamber 63 has a substrate delivery robot for delivering the substrate 67.

In addition, in the single-wafer type film formation apparatus 60, the load lock chamber 61 and the film-formation chamber 62 are arranged to correspond to each side of the rectangle with respect to the substrate delivery chamber 63.

In the load lock chamber 61, the substrate 67 to be subjected to the film-formation process or the substrate 67 to be subjected to the film-formation process is placed.

In addition, the load lock chamber 61 may include a delivery mechanism for delivering the substrate 67 to be subjected to the film-formation process or the substrate 67 to be subjected to the film-formation process.

In addition, a vacuum pump (not shown) is connected to the load lock chamber 61 in order to maintain the internal room in a vacuum state.

The substrate delivery chamber 63 is provided with a substrate delivery robot constructed to place the substrate 67 and deliver it between each chamber.

In the substrate delivery robot, a robot arm is provided to move in the horizontal or vertical direction.

The film-formation chamber 62 has the magnetron sputtering cathode 1 for performing film-formation on the surface of the substrate 67.

In the case where the DC power supply 68A is used as the power supply 68, the magnetron sputtering cathode 1 and the DC power supply 68A are arranged as shown in FIG. 14B.

In the case where the AC power supply 68B is used as the power supply 68, the magnetron sputtering cathode 1 and the AC power supply 68B are arranged as shown in FIG. 14C.

Since three film-formation chambers 62 are provided, it is possible to contract the throughput of a single substrate 67.

By applying the magnetron sputtering cathode 1 of the present invention to the single-wafer type film formation apparatus 60, it is possible to improve the utilization efficiency of the target 40, extend the lifetime of the target 40, reduce the labor cost for replacing the target 40, the material cost of the target 40, and the cost for bonding the target 40, reduce the downtime of the target 40, and improve productivity.

In addition, in comparison with the film formation apparatus having the vibrating cathode, the film formation apparatus of the present invention is compact.

In addition, since the vibration mechanism or the like is not necessary, it is possible to reduce the cost of the film formation apparatus.

Furthermore, in the case where the input power is fixed, the power is applied in a wide range, the power density per unit area is reduced, and it is advantageous in the arcing.

Roll-to-roll Type Film formation apparatus

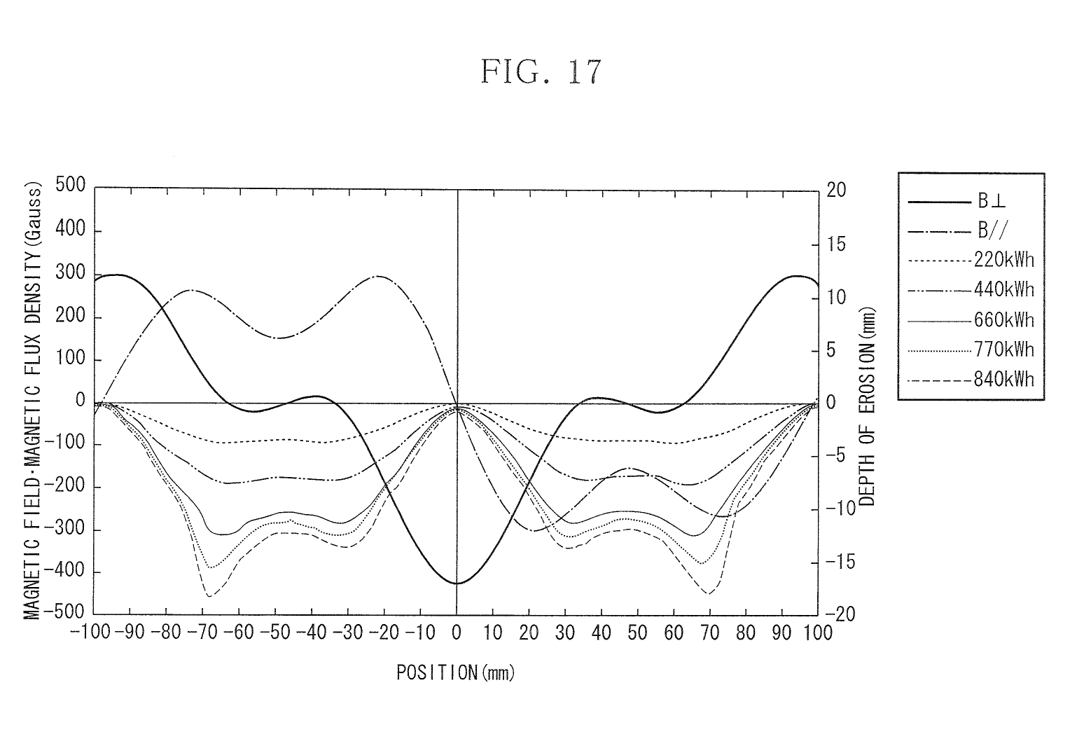

FIG. 15 is a cross-sectional view schematically illustrating a roll-to-roll type film formation apparatus 70 having the magnetron sputtering cathode 1 according to the present invention.

The roll-to-roll type film formation apparatus 70 includes a winder chamber 71, a sputter chamber 72, and a film-formation chamber 73.

The winder chamber 71, in which the substrate wound in a roll shape is held, at least includes a wind-off roll 74 for sequentially delivering the substrate, a plurality of guide rolls 75, and a take-up roll 76 for taking up the substrates that was subjected to the film-formation process.

The substrate is loaded on the wind-off roll 74.

In addition, the sputter chamber 72 is provided with a can 77 having a roll shape for holding the substrate to face an evaporation source and the magnetron sputtering cathode 1 of the present invention having the target 40.

First, the substrate is wound off from the wind-off roll 74, guided by a plurality of guide rolls 75 to be circumscribed with the can 77, and further passes through another guide roll 75 to reach the take-up roll 76 (by winding).

In circumference of the can 77, a plurality of magnetron sputtering cathodes 1 having the target 40 are provided, and a thin film is formed on the surface of the substrate wound by the can 77 using the sputtering technique.

Subsequently, the substrate where the thin film has been formed is guided by the guide roll 75 in the opposite side and wound by the take-up roll 76.

When the film-formation is made using such a sputtering technique, the inside of the roll-to-roll film formation apparatus 70 is always depressurized by a vacuum pump (not shown), and a functional gas or a reacting gas required in the film-formation is introduced to a cylinder (not shown).

The guide roll 75a used in the winding has a cooler within the guide roll so as to cool the substrate wound on the surface.

As the cooler, for example, a refrigerant pipe is provided inside the rotating roll.

If the magnetron sputtering cathode 1 of the present invention is applied to the roll-to-roll type film formation apparatus 70, it is possible to improve the utilization efficiency of the target 40, extend the lifetime of the target 40, reduce the labor cost for replacing the target 40, the material cost of the target 40, and the cost for bonding the target 40, reduce the downtime of the target 40, and improve the productivity.

In addition, in comparison with the film formation apparatus having the vibrating cathode, the film formation apparatus of the present invention is compact.

In addition, since the vibration mechanism or the like is not necessary, it is possible to reduce the cost of the film formation apparatus.

Furthermore, in the case where the input power is fixed, the power is applied in a wide range. Therefore, the power density per unit area is reduced, and it is advantageous in the arcing.

Carousel Type Film formation apparatus

FIG. 16 is a cross-sectional view schematically illustrating the carousel type film formation apparatus 80 having the magnetron sputtering cathode 1 of the present invention.

The carousel type film formation apparatus 80 includes a turbo-molecular pump 81, a mechanical booster pump 82, a rotary pump 83, and a vacuum chamber 84.

The vacuum chamber 84 is internally provided with a plurality of magnetron sputtering cathodes 1, a polygonal carousel substrate tray 85 in which a plurality of substrates 87 are laterally held, and an oxidizing source 86.

The vacuum chamber 84 is depressurized by a combination of the turbo-molecular pump 81, the mechanical booster pump 82, and the rotary pump 83.

The carousel substrate tray 85 shown in FIG. 16 is an octagonal column shape capable of laterally holding 8 substrates 87.

In addition, the carousel substrate tray 85 is not limited to the octagonal column shape, and octagonal or more angular column shapes may be used.

In this case, the number of the holding substrates 87 may be 8 or more.

A plurality of substrates 87 supplied to the inside of the vacuum chamber 84 are delivered to face the magnetron sputtering cathode 1 by rotation of the carousel substrate tray 85, and a thin film is formed on the substrate 87.

Then, the substrate 87 is delivered to the substrate feeding/fetching position by rotating the carousel substrate tray 85 and is ejected.

If the magnetron sputtering cathode 1 according to the present invention is applied to the carousel type film formation apparatus 80, it is possible to improve the utilization efficiency of the target 40, extend the lifetime of the target 40, reduce the labor cost for replacing the target 40, the material cost of the target 40, and the cost for bonding the target 40, reduce the downtime of the target 40, and improve the productivity.

In addition, in comparison with the film formation apparatus having the vibrating cathode, the film formation apparatus of the present invention is compact.

In addition, since the vibration mechanism or the like is not necessary, it is possible to reduce the cost of the film formation apparatus.

Furthermore, in the case where the input power is fixed, the power is applied in a wide range. Therefore, the power density per unit area is reduced, and it is advantageous in the arcing.

### EXAMPLES

### Example 1

The magnetron sputtering cathode shown in FIG. 1 was manufactured.

As the target, copper having a width of 200 mm and a thickness of 20 mm was used.

In addition, T/M was 35 mm, and the width of a yoke (SUS430) was 200 mm.

In addition, the height of each magnet portion was 30 mm, and the material thereof was NEOMAX HS-50AH.

The width of the central magnet portion was 15 mm, the width of the first auxiliary magnet portion was 12.5 mm, the width of the second auxiliary magnet portion was 7.5 mm, and the width of the peripheral edge magnet portion was 12.5 mm.

The distance from the central magnet portion to the first auxiliary magnet portion was 21 mm, the distance from the first auxiliary magnet portion to the second auxiliary magnet portion was 20 mm, the distance from the second auxiliary magnet portion to the peripheral edge magnet portion was 15 mm, and the distance from the peripheral edge magnet portion to the end of the yoke was 6.5 mm.

Electric discharge was carried out for a long period to check the erosion formed in the target.

The result is shown in FIG. 17.

In FIG. 17, the axis of abscissas denotes the position of the widthwise direction of the magnetron sputtering cathode, and the axis of ordinate denotes the depth of the erosion and the magnetic flux density.

In addition, on the axis of abscissas in FIG. 17, the position of 0 mm corresponds to the position of the central magnet portion. In other words, the axis of abscissas in FIG. 17 denotes the distance from the central magnet portion.

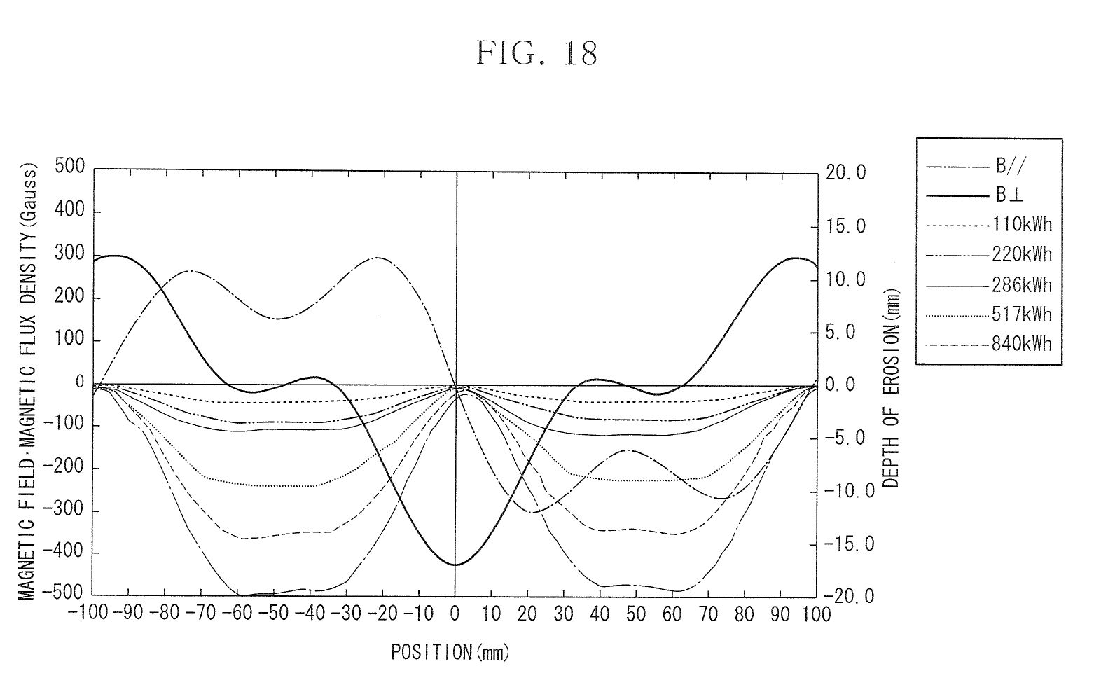

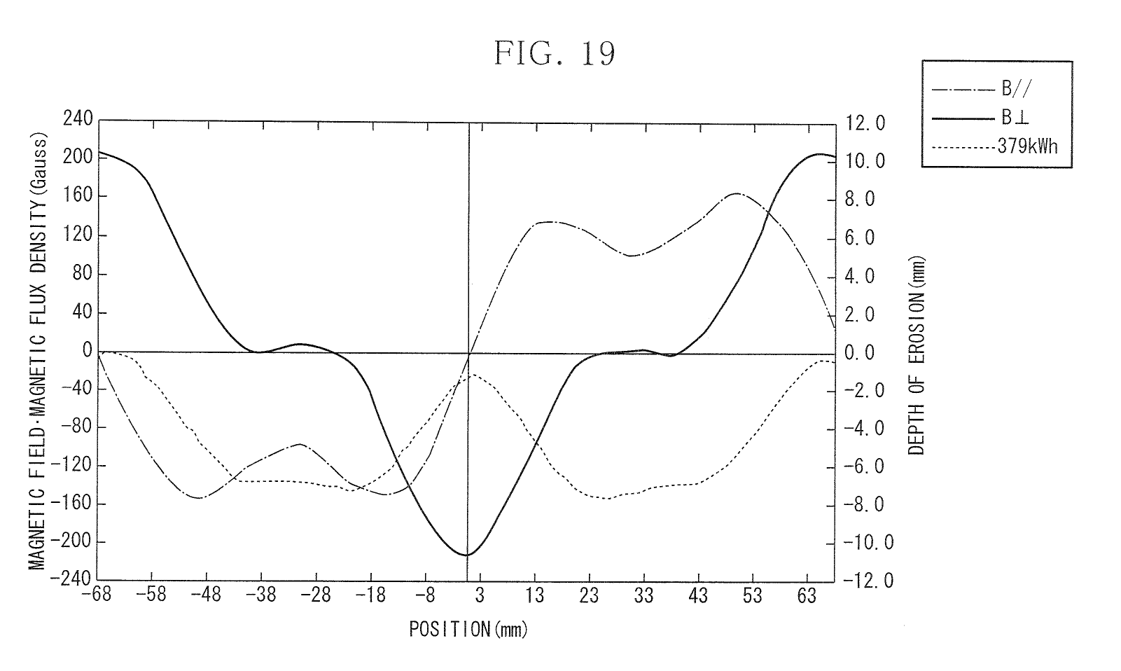

In addition, the axis of ordinate and the axis of abscissas described below in FIGS. 18 and 19 are similar to those of FIG. 17.

As shown in FIG. 17, if the depth of the erosion exceeds approximately 12.5 mm, the one-sided hollow of erosion is observed.

This is because, as erosion progresses, the electric energy (watt-hour) increases, and thus, the maximum intensity increases in the magnetic flux density (B_{//}) of the horizontal direction as shown in FIG. 17.

In this case, if the T/M becomes below 25 mm, and the maximum intensity exceeds 600 gauss, the sign of the value in the bottom of the distribution of the magnetic flux density (B_{//}) of the horizontal direction is reversed as shown in FIGS. 3A and 3B.

As a result, in the bottom of the distribution of the magnetic flux density (B_{//}) of the horizontal direction, the Lorentz force applied to electrons is reversed. Therefore, plasma is apt to be locally concentrated and divided into two parts.

For this reason, the one-sided hollow is generated in the target.

This is because the magnetron sputtering cathode of Example 1 is manufactured based on a design for obtaining an ideal magnetic field when the T/M is 35 mm, and thus, as the T/M is less than 25 mm, the ideal magnetic field varies.

This can be avoided by introducing a control unit for lowering the entire magnetic circuit in the Z-axis direction from the surface of the target as shown in Example 2 described below.

In addition, the utilization efficiency of the target was approximately 50% in Example 1.

### Example 2

In Example 2, a control unit for lowering the entire magnetic circuit from the surface of the target in the Z-axis direction before the value in the bottom of the distribution of the magnetic flux density (B_{//}) of the horizontal direction is reversed was introduced into the magnetron sputtering cathode of Example 1.

In Example 2, if erosion progresses 5 mm from the watt-hour, the magnetic circuit was lowered by 5 mm.

The result is shown in FIG. 18.

Referring to FIG. 18, even when the depth of the erosion exceeds approximately 12.5 mm, the one-sided hollow was improved, and the utilization efficiency of the target was greater than or equal to 60%.

### Example 3

The magnetron sputtering cathode shown in FIG. 1 was manufactured.

As the target, copper having a width of 135 mm and a thickness of 12 mm was used.

In addition, T/M was 27 mm, and the width of a yoke (SUS430) was 135 mm.

The height and the material of the magnet portion were similar to those of Example 1.

In addition, the width of the central magnet portion was 12.5 mm, the width of the first auxiliary magnet portion was 9.5 mm, the width of the second auxiliary magnet portion was 7.5 mm, and the width of the peripheral edge magnet portion was 10.0 mm.

The distance from the central magnet portion to the first auxiliary magnet portion was 9 mm, the distance from the first auxiliary magnet portion to the second auxiliary magnet portion was 15.5 mm, and the distance from the second auxiliary magnet portion to the peripheral edge magnet portion was 7 mm.

Electric discharge was carried out as in Example 1, and the erosion formed in the target was checked.

The result is shown in FIG. 19.

As shown in FIG. 19, the target was hollowed by approximately 8 mm out of the thickness of 12 mm, and the utilization efficiency was 60%. If the target is used to the end, it is anticipated that the utilization efficiency will reach 70% or more.

Consequently, if the magnetron sputtering cathode according to the present invention is used for the surface of the target, it is recognized that the cathode having a high utilization efficiency greater than or equal to 60% can be obtained regardless of the material of the magnet, the distance between the magnets, and the construction of the magnetic circuit.

Furthermore, since the Z-axis is used, the target having a thickness greater than or equal to 20 mm can be used in the present invention. Therefore, it was recognized that the use lifetime of the target can be extended.

### INDUSTRIAL APPLICABILITY

The present invention can be applied to the film formation apparatus having the magnetron sputtering cathode. In comparison with a conventional magnetron sputtering cathode, it is possible to increase the utilization efficiency of the target, and at the same time, the present invention can be applied even when the thickness of the target exceeds 20 mm.

What is claimed is:

1. A magnetron sputtering cathode comprising:
a yoke having a plate shape and having a surface and a central area;
a magnetic circuit provided at the surface of the yoke, the magnetic circuit having a central magnet portion that is linearly disposed at the central area of the yoke, a peripheral edge magnet portion that is disposed in the periphery of the central magnet portion, an auxiliary magnet portion that is disposed between the central magnet portion and the peripheral edge magnet portion, and a parallel area where the central magnet portion, the peripheral edge magnet portion, and the auxiliary magnet portion are parallel to each other; and
a backing plate disposed so as to be superimposed on the magnetic circuit, wherein
the central magnet portion, the peripheral edge magnet portion, and the auxiliary magnet portion are disposed so that polarities of tip portions of the central magnet portion, the peripheral edge magnet portion, and the auxiliary magnet portion are different from each other at portions between adjacent magnet portions,
in a cross direction which crosses the central magnet portion, the peripheral edge magnet portion, and the auxiliary magnet portion in the parallel area, and in an axial direction orthogonal to a direction in which the central magnet portion is extended, a magnetic field profile is obtained by observing toward the peripheral edge magnet portion from the central magnet portion and by observing from above of the backing plate, and
a magnetic flux density in a horizontal direction in the magnetic field profile on a face parallel to the backing plate is determined so that the magnetic flux density in a first area is a positive value and the magnetic flux density in a second area is a negative value with respect to a position corresponding to the central magnet portion as a boundary.

2. The magnetron sputtering cathode according to claim 1, wherein the positive or negative sign of value of the magnetic flux density of the horizontal direction is reversed at the near peripheral edge magnet portion.

3. The magnetron sputtering cathode according to claim 1,
wherein a magnetic flux density in a vertical direction on a surface parallel to the backing plate is symmetrical with respect to a position corresponding to the central magnet portion as a boundary, and
each of the first area and the second area has three points where the magnetic flux density in the vertical direction is zero.

4. The magnetron sputtering cathode according to claim 1, wherein the maximum intensity of the magnetic flux density in the horizontal direction is 100 gauss to 600 gauss.

5. The magnetron sputtering cathode according to claim 1, further comprising:
a control unit adjusting a distance between the backing plate and the magnetic circuit.

6. A film formation apparatus comprising the magnetron sputtering cathode according to claim 1.
